(19) United States
(12) Patent Application Publication
(10) Pub. No.: US 2026/0079410 A1
(43) Pub. Date: Mar. 19, 2026

(54) A PATTERNING DEVICE VOLTAGE BIASING SYSTEM FOR USE IN EUV LITHOGRAPHY

(71) Applicant: ASML Netherlands B.V., Veldhoven (NL)

(72) Inventors: Derk Servatius Gertruda BROUNS, Herentals (BE); Andrey NIKIPELOV, Eindhoven (NL); Selwyn Yannick Frithjof CATS, Eindhoven (NL); Parham YAGHOOBI, Eindhoven (NL); Christian Gerardus Norbertus Hendricus Marie CLOIN, Eindhoven (NL); Andrei Mikhailovich YAKUNIN, Veldhoven (NL); Hariprasad MYLAPRAVAN GANGADHARAN, Eindhoven (NL)

(73) Assignee: ASML Netherlands B.V., Veldhoven (NL)

(21) Appl. No.: 18/875,601

(22) PCT Filed: Sep. 8, 2023
(86) PCT No.: PCT/EP2023/074779

§ 371 Date: Dec. 16, 2024

(30) Foreign Application Priority Data
May 31, 2023 (EP) 23176443.2
Sep. 13, 2023 (EP) 22195470.4

(51) Int. Cl. G03F 7/00

(52) U.S. Cl. CPC G03F 7/70916; G03F 7/70983; G03F 7/70991

(57) ABSTRACT

A patterning device voltage biasing system for use in a lithographic apparatus, the patterning device voltage biasing system comprising: a patterning device configured to impart a pattern to a beam of radiation, the patterning device comprising a patterning surface with a pattern thereon; and a voltage source, wherein the patterning device voltage biasing system is configured such that a voltage can be applied to the patterning surface of the patterning device by the voltage source.

### CROSS-REFERENCE TO RELATED APPLICATIONS

This application claims priority of EP Application Serial No. 22195470.4 which was filed on 13 Sep. 2022 and EP Application Serial No. 23176443.2 which was filed on 31 May 2023 which are incorporated herein in its entirety by reference.

### FIELD

The present invention relates to a patterning device voltage biasing system for use in a lithographic apparatus, a lithographic apparatus comprising a patterning device voltage biasing system, a method of reducing contamination on a patterning surface of a patterning device in a lithographic apparatus, and a method of manufacturing a device comprising method of reducing contamination on a patterning surface of a patterning device in a lithographic apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Lithography is widely recognized as one of the key steps in the manufacture of ICs and

other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} * \frac{λ}{N A} \qquad ( 1 )$$

where A is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from Equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

Once the EUV radiation has been generated, it is directed through the lithographic apparatus by a plurality of mirrors to a patterning surface of the patterning device, which imparts the desired pattern to the EUV radiation. As a result of the photoelectric effect, the EUV radiation incident on the patterning surface causes electrons to be ejected from the surface. The patterning surface may be electrically isolated from a grounded frame of the lithographic apparatus. This may be because the patterning surface is provided on a dielectric substrate, such as an ultra-low expansion glass substrate. Consequently, the ejection of electrons from the patterning surface causes the patterning surface to become positively charged.

Contaminant particles may be present in the environment surrounding the patterning device. The contaminant particles may become negatively charged by absorbing the electrons ejected from the patterning surface as a result of the photoelectric effect, and by absorbing electrons from plasma generated from gas particles that are excited by the EUV radiation.

The negatively charged contaminant particles are attracted to the positively charged patterning surface, which means that the contaminant particles are accelerated towards the patterning surface. Consequently, it is likely that contaminant particles within the environment surrounding the patterning device will be deposited onto the patterning surface. The presence of contaminant particles on the patterning surface can cause imaging errors, which reduces the yield of the lithographic process.

An object of the present invention is to improve the yield of an EUV lithographic process by preventing contaminant particles from being deposited on a patterning surface of a patterning device.

### SUMMARY OF THE INVENTION

According to an aspect of the present invention, there is provided a patterning device voltage biasing system for use in a lithographic apparatus, the patterning device voltage biasing system comprising:
a patterning device configured to impart a pattern to a beam of radiation, the patterning device comprising a patterning surface with a pattern thereon; and
a voltage source,
   wherein the patterning device voltage biasing system is configured such that a voltage can be applied to the patterning surface of the patterning device by the voltage source.

According to another aspect of the present invention, there is provided a method of reducing contamination on a patterning surface of a patterning device in a lithographic apparatus, the method comprising:
a contacting step in which a conductive member is brought into contact with the patterning surface;
a voltage biasing step in which a voltage is provided to the patterning surface from a voltage source, via the conductive member.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 schematically depicts a lithographic apparatus.

FIG. 2 schematically depicts a more detailed view of the lithographic apparatus.

FIG. 3 schematically depicts a patterning device whilst being exposed to EUV radiation.

FIG. 4A depicts a plot of Voltage of a Patterning Surface against Time for the case that a bias voltage is not applied.

FIG. 4B depicts a plot of Voltage of a Patterning Surface against Time for the case that a bias voltage is applied.

FIG. 5A depicts a plot of Distance from a Patterning Surface against Time for the case that a bias voltage is not applied.

FIG. 5B depicts a plot of Distance from a Patterning Surface against Time for the case that a bias voltage is applied.

FIG. 6 schematically depicts an embodiment of a patterning device voltage biasing system in a non-contacting arrangement.

FIG. 7 schematically depicts an embodiment of a patterning device voltage biasing system in a contacting arrangement.

FIG. 8 schematically depicts an embodiment of a patterning device voltage biasing system in a landed arrangement.

FIG. 9 schematically depicts another embodiment of a patterning device voltage biasing system.

FIG. 10 schematically depicts another embodiment of a patterning device voltage biasing system.

FIG. 11 schematically depicts a patterning device support in accordance with an embodiment of the present invention.

FIG. 12A depicts a plan view of a patterning surface of a patterning device.

FIG. 12B schematically depicts a cross-sectional view of the patterning device depicted in FIG. 12A.

FIG. 12C depicts a plan view of a non-patterning surface of the patterning device depicted in FIGS. 12A and 12B.

FIG. 13A depicts a plan view of a patterning surface of a patterning device, in accordance with the embodiments of present invention.

FIG. 13B depicts a cross-sectional view of the patterning device s depicted in FIG. 13A.

FIG. 14A depicts a plan view of a patterning surface of a patterning device, in accordance with an embodiment of the present invention.

FIG. 14B depicts a cross-sectional view of a patterning device, which may be a first implementation of the patterning device depicted in FIG. 14A.

FIG. 14C depicts a cross-sectional view of another patterning device, which may be a second implementation of the patterning device depicted in FIG. 14A.

FIG. 15A depicts a plan view of a patterning surface of a patterning device, in accordance with an embodiment of the present invention.

FIG. 15B depicts a cross-sectional view of a patterning device, which may be a first implementation of the patterning device depicted in FIG. 15A.

FIG. 15C depicts a cross-sectional view of another patterning device, which may be a second implementation of the patterning device depicted in FIG. 15A.

FIG. 16A depicts a plan view of a patterning surface of a patterning device, in accordance with an embodiment of the present invention.

FIG. 16B depicts a cross-sectional view of the patterning device depicted in FIG. 16A.

FIG. 16C depicts a plan view of a non-patterning surface of the patterning device depicted in FIGS. 16A and 16B.

FIG. 17A depicts a plan view of a patterning surface of a patterning device, in accordance with an embodiment of the present invention.

FIG. 17B depicts a cross-sectional view of the patterning device depicted in FIG. 17A.

FIG. 17C depicts a plan view of a non-patterning surface of the patterning device depicted in FIGS. 17A and 17B.

FIG. 18A depicts a plan view of a patterning surface of a patterning device, in accordance with an embodiment of the present invention.

FIG. 18B depicts a cross-sectional view of the patterning device depicted in FIG. 18A.

FIG. 18C depicts a plan view of a non-patterning surface of the patterning device depicted in FIGS. 18A and 18B.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

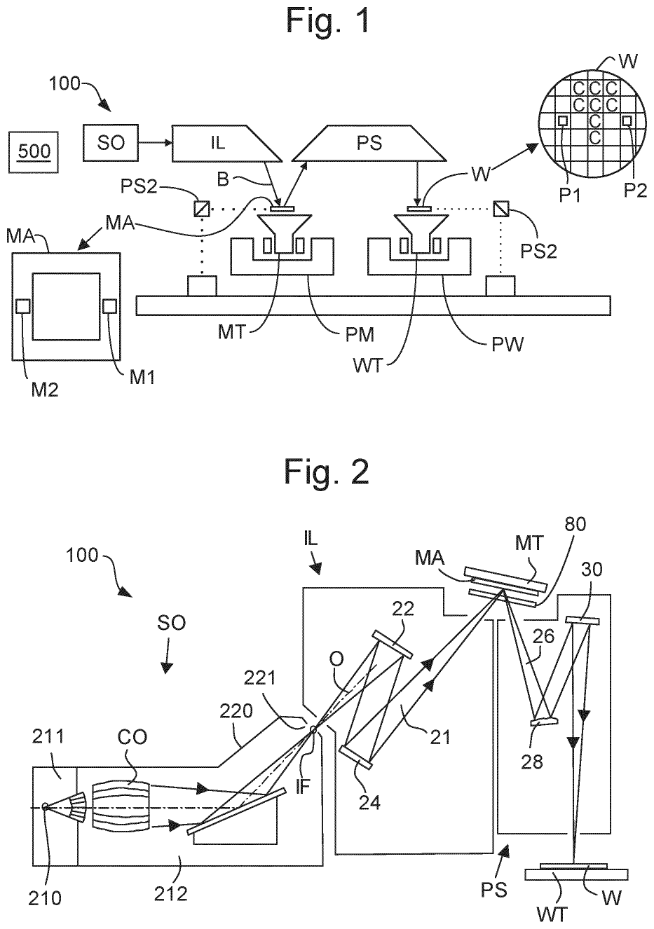

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

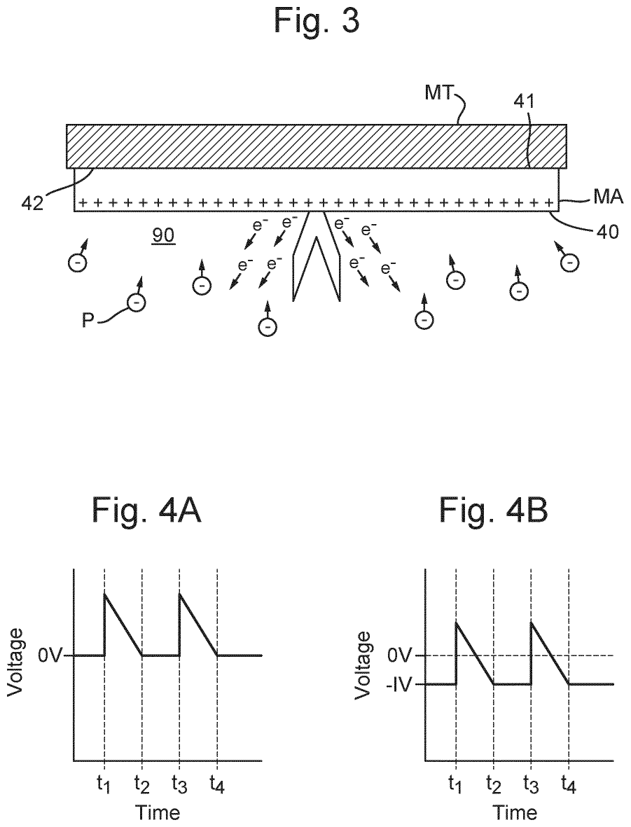

FIG. 3 depicts a schematic representation of a patterning device MA clamped to a support structure MT. As described above, the support structure MT may use mechanical, vacuum, electrostatic or other clamping techniques to hold the patterning device MA. The support structure MT may comprise a plurality of burls (cone-shaped protrusions) on a supporting surface 42 of the support structure MT that faces a non-patterning surface 41 of the patterning device MA. When the patterning device MA is clamped to the support structure MT, the non-patterning surface 41 is in contact with distal ends of the plurality of burls. It is not necessary for each of the plurality of burls to be in contact with the non-patterning surface 41. These burls are not shown in FIG. 3.

Both the patterning device MA and support structure MT may be contained within a patterning device environment 90. The patterning device environment 90 may be separated from an external environment surrounding the lithographic apparatus 100 and/or other components within the lithographic apparatus such that gases and contaminant particles P are substantially prevented from entering the patterning device environment 90.

The patterning device environment 90 may be partially evacuated of gas. That is, the pressure within the patterning device environment 90 may be less than ambient pressure. This is to limit the attenuation of EUV radiation as it travels through the patterning device environment 90. Even though the pressure within the patterning device 90 is less than ambient pressure, it is not a perfect vacuum, so gas particles are present in the patterning device environment 90.

Contaminant particles P may also be present in the patterning device environment 90. Despite the separation of the patterning device environment 90 from the external environment and/or other components within the lithographic apparatus, it is possible that some contaminant particles P may enter the patterning device environment 90 from these locations. Also, contaminant particles P may be generated within the patterning device environment 90 by mechanisms such as abrasive wear, which occurs when there is relative motion between contacting surfaces.

During EUV lithography, the unpatterned beam 21 is incident on a patterning surface 40 of the patterning device MA. This causes the release of electrons from the patterning surface 40 by the photoelectric effect.

The patterning surface 40 may be electrically isolated or electrically floating. Consequently, the patterning surface 40 becomes positively charged. The patterning surface 40 may be conductive. For example, the patterning surface may be formed, at least in part, of a metal. For example, the patterning surface may be formed, at least in part, of Ruthenium.

The EUV radiation within the patterning device environment 90 also causes contaminant particles P to become negatively charged. This occurs as a result of at least two main mechanisms. A first mechanism is a result of the formation of plasma from the gas molecules within the patterning device environment 90, which are excited by the EUV radiation. Free electrons within the plasma may be absorbed by the contaminant particles P, resulting in those particles becoming negatively charged. A second mechanism is a consequence of the photoelectric effect which causes the patterning surface 40 to become positively charged. Specifically, electrons that have been ejected from the patterning surface 40 as a result of the photoelectric effect may be absorbed by the contaminant particles P, causing them to become negatively charged.

As a result of the patterning surface 40 becoming positively charged and the contaminant particles P becoming negatively charged, an attractive electrostatic force is exerted between the patterning surface 40 and the contaminant particles P. This causes the contaminant particles P to accelerate towards the patterning surface 40. Consequently, it is likely that contaminant particles within the lithographic apparatus will be deposited onto the patterning surface 40.

In EUV lithographic systems, EUV radiation is typically generated in pulses. That is, there are periods when EUV radiation is generated, and periods when it is not. In the periods when the EUV pulse is not generated, the patterning surface 40 may be discharged, i.e., the magnitude of the positive charge on the patterning surface 40 may decrease. This may be such that the patterning surface 40 becomes approximately neutral. The discharging of the patterning surface 40 may be caused by the plasma that is formed within the patterning device environment 90 from the gas particles excited by the EUV radiation. Specifically, electrons within the plasma may be attracted to the patterning surface 40, where they are absorbed by positive ions on the patterning surface 40. Pulses of EUV radiation are typically generated at a rapid frequency. This frequency may be, for example, approximately 50 kHz, approximately 60 kHz, or approximately 100 kHz. This means that, during an EUV lithographic process, a patterning surface 40 may cycle between being positively charged and being approximately neutral at a high frequency.

To prevent contaminant particles P accelerating towards the patterning surface 40 as a result of electrostatic attraction, a voltage biasing system may be used, in which a bias voltage is applied to the patterning surface 40 of the patterning device. This bias voltage may be negative. That is, a bias voltage may be applied to the patterning surface 40 such that the patterning surface 40 becomes negatively charged, meaning that that the negatively charged contaminant particles P within the patterning device environment 90 are repelled from the patterning surface 40. The magnitude of the voltage applied to the patterning surface 40 may be greater than 0.5 V and preferably greater than 1 V. This is because a voltage of this magnitude may be necessary to ensure that the distance between the patterning surface 40 and contaminant particles P increases over time. The magnitude of the voltage applied to the patterning surface 40 may also be less than 10 V, preferably less than 5 V and further preferably less than 3 V. Voltages in excess of these values may result in an excessively large current being drawn through the patterning surface 40. This can cause the patterning surface 40 to heat up and deform, which can reduce the quality of the pattern projected from the patterning surface 40 to the substrate W.

In the present application, the terms “voltage” and “bias voltage” may also be referred to as a “potential” or a “bias potential”. Voltages may be relative to the ground. Voltages may be relative to a local ground, such as a grounded frame of the lithographic apparatus. For example, if a negative bias voltage is applied to a surface, this may mean that the potential of the surface is negative relative to the grounded frame of the lithographic apparatus.

FIGS. 4A and 4B depict plots of voltage of the patterning surface 40 against time. FIG. 4A shows voltage of the patterning surface 40 without voltage biasing of the patterning surface 40 during the EUV lithography process. FIG. 4B shows voltage of the patterning surface 40 where voltage biasing of the patterning surface 40 is applied. The plot in FIG. 4B does not relate directly to a specific method by which the bias voltage is applied to the patterning surface 40.

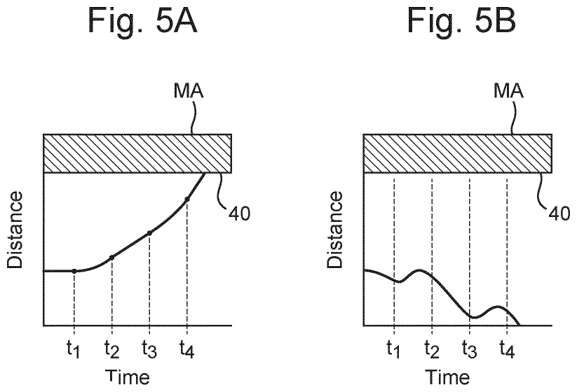

FIGS. 5A and 5B depict plots of the displacement of a contaminant particle P relative to the patterning surface 40 over time. FIG. 5A shows the displacement of a contaminant particle P without voltage biasing of the patterning surface during the EUV lithography process. FIG. 5B shows the displacement of a contaminant particle P where voltage biasing of the patterning surface is applied. The plot in FIG. 5B does not relate directly to a specific method by which the bias voltage is applied to the patterning surface 40. The circumstances underlying the plot depicted in FIG. 4A correspond to the circumstances underlying the plot depicted in FIG. 5A, and the circumstances underlying the plot depicted in FIG. 4B correspond to the circumstances underlying the plot depicted in FIG. 5B. For FIGS. 4B and 5B, the bias voltage applied to the patterning surface 40 is a constant bias voltage of approximately −1 V.

FIG. 4A shows that, without the application of a bias voltage, the voltage of the patterning surface 40 begins at approximately 0 V. At t=t₁, a pulse of EUV radiation is generated by the lithographic apparatus 100, which causes the voltage of the patterning surface 40 to rapidly increase, reaching a maximum at the point that the pulse of EUV radiation terminates. After this point, the voltage of the patterning surface 40 decreases as the patterning surface discharges, reaching approximately 0 V by t=t₂. This process is repeated when the next pulse of EUV radiation is generated at t=t₃.

In FIG. 5A, the contaminant particle P is initially at rest in the direction perpendicular to the surface 40. When the pulse of EUV radiation is initiated (t=t₁), the contaminant particle P begins to accelerate towards the patterning surface 40. As the patterning surface 40 discharges, the magnitude of this acceleration decreases. Once the charge of the patterning surface 40 has returned to approximately 0V (t=t₂), the contaminant particle P no longer accelerates towards the patterning surface 4, but continues to travel towards the patterning surface 40 at a constant velocity. As the second pulse of EUV radiation is initiated (at t=t₃), the contaminant particle P again begins to accelerate towards the patterning surface 40. Before the next pulse of EUV radiation is generated, the displacement between the contaminant particle P and the patterning surface 40 becomes zero, i.e., the contaminant particle 40 is deposited into the patterning surface 40.

FIGS. 4A and 5A only depict two pulses of EUV radiation. After these two pulses, the contaminant particle P is deposited onto the patterning surface 40. In practice, many more pulses of EUV radiation may be required to sufficiently accelerate the contaminant particle P such that it travels the distance between its initial position and the patterning surface 40. However, because the frequency of the pulses of EUV radiation in a typical lithographic apparatus is high, the effect of the EUV radiation on the path of the particle over time is large, even if the magnitude of the acceleration of the contaminant particle P towards the patterning surface 40 is relatively low.

In FIG. 4B, the bias voltage applied to the patterning surface 40 is −1 V. Therefore, before the initiation of the first pulse of EUV radiation, the voltage of the patterning surface 40 is approximately −1 V. When the pulse of EUV radiation is initiated (at t=t₁), as in the case where there is no bias voltage applied, the voltage of the patterning surface 40 increases. FIG. 4B shows that this is such that the voltage of the patterning surface 40 becomes greater than 0 V (i.e., the patterning surface 40 becomes positively charged). However, this is not necessarily the case, and the magnitude of the negative bias voltage applied to the patterning surface 40 may be sufficient for the voltage of the patterning surface 40 to remain below 0 V (i.e., for the patterning surface 40 to remain negatively charged) throughout the duration of each pulse of EUV radiation. The voltage of the patterning surface 40 reaches a maximum at the termination of the pulse of EUV radiation. After the pulse of EUV radiation, the patterning surface 40 is discharged, such that the voltage of the patterning surface 40 becomes the same as the bias voltage applied to the patterning surface (at t=t₂). As in the case where no bias voltage is applied to the patterning surface 40, discharging is caused by the plasma within the patterning device environment 90. However, discharging is also caused by the application of the negative bias voltage. As a result of this, the rate of discharge of the patterning surface 40 is faster. Consequently, the length of time t₁ to t₂ (and t₃ to t₄) is smaller in the case that a negative bias voltage is applied to the patterning surface 40 than in the case where a negative bias voltage is not applied to the patterning surface.

In FIG. 5B, which depicts the position of a contaminant particle P relative to the patterning surface 40 over time for the case where a bias voltage is applied to the patterning surface 40, the contaminant particle P is initially at rest in the direction perpendicular to the patterning surface 40. At this point, the voltage of the patterning surface 40 is approximately −1 V, which means that the contaminant particle P is repelled by the patterning surface 40, and accelerates away from the patterning surface 40. As the pulse of EUV radiation is initiated (at t=t₁) and the voltage of the patterning surface 40 becomes positive, the particle accelerates towards the patterning surface 40. In FIG. 5B, this is such that the direction of travel of the contaminant particle P is reversed, and the particle briefly travels towards the patterning surface 40. However, this may not be the case, and the acceleration of the contaminant particle P towards the patterning surface 40 may only be such that the contaminant particle P continues to travel away from the patterning surface 40, but with a decreasing velocity. In a case where the pulse of EUV radiation does not cause the voltage of the patterning surface 40 to become positive, the contaminant particle will not accelerate towards the patterning surface 40 at all. In this case, the contaminant particle P would continue to accelerate away from the patterning surface 40, but the magnitude of this acceleration would be temporarily reduced.

Returning to the scenario shown in FIG. 5B, as the pulse of EUV radiation terminates and the voltage of the patterning surface 40 becomes negative, the contaminant particle P once again accelerates away from the patterning surface 40. This process is repeated when the second pulse of EUV radiation is initiated.

The time in which the contaminant particle 40 accelerates towards the patterning surface 40 may be sufficiently small such that, over time, the distance between the contaminant particle P and the patterning surface 40 increases. Consequently, the contaminant particle P is not deposited onto the patterning surface 40.

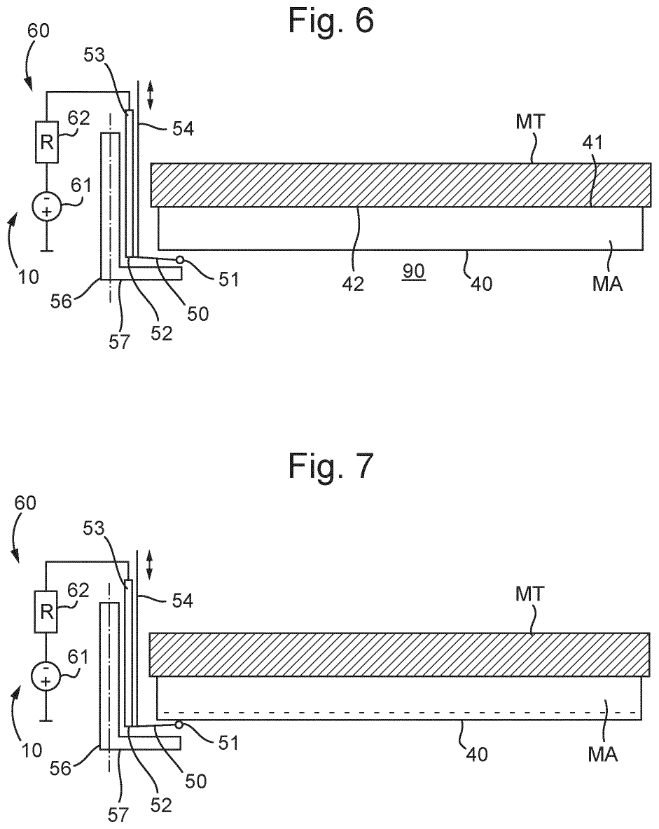

Embodiments of a patterning device voltage biasing system are shown in FIGS. 6 to 18. The patterning device voltage biasing system comprises a patterning device MA and a voltage source 61. The patterning device voltage biasing system is configured such that the voltage source 61 can apply a bias voltage to a patterning surface 40 of the patterning device MA. This bias voltage may be a negative bias voltage. The embodiments described below are intended to be exemplary, and the present invention is not limited to the application of a bias voltage to a patterning surface by these exact methods.

### First Embodiment

FIGS. 6 to 8 depict a patterning device voltage biasing system 10 comprising a patterning device MA, a voltage source 61, and a conductive member 50, which is electrically connected to the voltage source 61. This conductive member 50 is configured to contact a patterning surface 40 of the patterning device MA during the lithographic process, such that a negative bias voltage can be applied to the patterning surface 40.

In the following description, a vertical direction is a direction such that, when the patterning device MA is supported by the support structure MT, the patterning device MA is below the support structure MT in the vertical direction. The vertical direction may alternatively be referred to as a first direction. The terms “radially outwards” and “radially inwards” are used in relation to the centre of the patterning device MA, with the radial direction being perpendicular to the vertical direction.

The patterning device voltage biasing system 10 may be configured such that the system can transition between a non-contacting arrangement (FIG. 6) and a contacting arrangement (FIG. 7). In the non-contacting arrangement, the conductive member 50 is distanced from the patterning surface 40 in the vertical direction. This may be such that the negative bias voltage is not applied to the patterning surface 40. In the contacting arrangement, the conductive member 50 is in contact with the patterning surface 40 such that the negative voltage can be applied to the patterning surface 40. The contacting arrangement and the non-contacting arrangement are equivalent to the first arrangement and the second arrangement of the claims, respectively.

The conductive member 50 may be configured to contact a region of the patterning surface 40 that is not critical to the pattern projected from the patterning device MA. That is, the conductive member 50 may be configured to contact the patterning surface 40 in a region where doing so does not result in a change to the pattern projected from the patterning surface 40. For example, this may be a region on the patterning surface 40 where no pattern is present.

The patterning device voltage biasing system 10 may be arranged such that, as the system transitions from the non-contacting arrangement to the contacting arrangement and the conductive member 50 comes into contact with the patterning surface 40. This may be such that the conductive member 50 exerts a contact force onto the patterning surface 40. This contact force may ensure that the electrical connection between the conductive member 50 and the patterning surface 40 is consistent, such that the bias voltage is reliably supplied to the patterning surface 40 via the conductive member 50.

The conductive member 50 may be a compliant member. That is, the conductive member 50 may be capable of elastic deformation. In the example shown in FIGS. 6 to 8, the conductive member 50 is a leaf spring. However, this is not essential, and other types of conductive member 50 may be successfully implemented. The exact material of the conductive member 50 is not particularly limited. However, the material should be conductive and capable of a certain degree of elastic deformation. Further, the material should not generate contaminant particles when deformed.

The conductive member 50 may be disposed within the patterning device voltage biasing system 10 such that a portion of the conductive member 50 is beneath the patterning device MA. That is, the patterning device MA and the conductive member may overlap in the radial direction.

The conductive member 50 may be supported at a first end portion 52. In the example shown in FIG. 6, the first end portion 52 of the conductive member 50 is supported by a conductive member support 53. The conductive member support 53 may fix the position of the first end portion 52 of the conductive member 50 relative to other components within the patterning device voltage biasing system, such as the support structure MT. A second end portion 51, which is at an opposite end to the first end portion 52, may be configured to contact the patterning surface 40. The first end portion 52 of the conductive member 50 is located radially outwards of the second end portion 51 of the conductive member 50. The conductive member support 53 and the first end portion 52 of the conductive member 50 may be located radially outwards of the edge of the patterning device MA. The second end portion 51 of the conductive member 50 may be arranged radially inwards of the edge of the patterning device MA.

The second end portion 51 of the conductive member 50 may comprise a contacting region to improve the consistency of the electrical connection between the conductive member 50 and the patterning surface 40. The contacting region may be in the form of a beveled protrusion. Like the conductive member 50, the contacting region may also be formed of a conductive material. The contacting region may be formed of the same material as the conductive member 50.

A conductive member actuator 54 may be attached to the conductive member 50 between the first end portion 52 and the second end portion 51. That is, the conductive member actuator 54 may be attached to the conductive member 50 at a position that is radially outwards of the second end portion 51 of the conductive member 50 and radially inwards of the first end portion 51 of the conductive member 50.

The conductive member actuator 54 may be configured to move in the vertical direction.

That is, the conductive member actuator 54 may be configured to move the portion of the conductive member 50 at which the conductive member actuator 54 is attached to the conductive member 50 in the vertical direction. In doing this, the conductive member actuator 54 may rotate the conductive member 50 about the first end portion 52.

In the non-contacting arrangement, the conductive member 50 may be in a non-contacting position, and in the contacting arrangement, the conductive member 50 may be in a contacting position. The non-contacting position and contacting position correspond to the first position and the second position of the claims, respectively. To move the conductive member 50 from the non-contacting position to the contacting position, the conductive member actuator 54 may move vertically upwards, causing the conductive member 50 to rotate. In the schematic representations depicted in FIGS. 6 to 8, this rotation is in the anti-clockwise direction.

The patterning device voltage biasing system 10 may be configured such that, when the conductive member 50 rotates from the non-contacting position to the non-contacting position, the second end portion 51 does not slide along the patterning surface 40. As stated above, sliding motion can lead to abrasive wear, which contributes to the generation of contaminant particles. To ensure that the second end portion 51 does not slide along the patterning surface 40 during the rotation of the conductive member, the patterning device voltage biasing system 10 may be configured such that the axis around which the second end portion rotates is in the plane of the patterning surface 40.

The conductive member support 53 may support the conductive member 50 such that the first end portion 52 of the conductive member 50 cannot rotate relative to conductive member support 53. That is, the conductive member may be a cantilever. Allowing rotation of the first end portion 52 relative to the conductive member support 53 would result in relative motion between contacting surfaces of the conductive member 50 and conductive member support 53. Such sliding motion may cause abrasive wear, which can lead to the generation of contaminant particles P. When the conductive member support 53 supports the conductive member 50 such that the first end portion 52 of the conductive member 50 cannot rotate relative to conductive member support 53, the rotation of the conductive member 50 about the first end portion 52 involves deformation of the conductive member 50. Preferably, this deformation is elastic deformation.

The displacement of the conductive member 50 between the non-contacting position and the contacting position may be relatively small. This is to avoid excess deformation of the conductive member 50, which could contribute to material degradation due to fatigue. This could lead to the generation of contaminant particles P in the patterning device environment 90, and could eventually result in the complete failure (i.e., fracture) of the conductive member 50. For example, the angle of rotation of the conductive member about the first end portion may be less than 10 degrees, preferably less than 5 degrees, and preferably less than 1 degree. The angle of rotation can be defined as the angle between a first line, which is a line that connects the first portion 52 and the second portion 51 when the conductive member 50 is in the non-contact position, and a second line which connects the first portion 52 and the second portion 51 when the conductive member 50 is in the contact position.

At some point on the path of the conductive member 50 from the non-contacting position to the contacting position, the second end portion 51 of the conductive member 50 may come into contact with the patterning surface 40. This prevents the second end portion 51 of the conductive member 50 from continuing to rotate in accordance with the upward movement of the conductive member actuator 54 and the continued rotation of the rest of the conductive member 50. Consequently, the second end portion 51 of the conductive member 50 exerts a force on the patterning surface 40. This force is in a direction opposite to the direction of the movement of the actuator as it deforms the conductive member from the non-contact position to the contact position. In the patterning device voltage biasing system 10 depicted in FIGS. 6 to 8, this is in the vertically upwards direction. As explained above, this force ensures that the conductive member 50 and the patterning surface 40 remain in stable contact throughout the lithographic process, which ensures that the bias voltage is consistently applied to the patterning surface 40.

The step described above, in which the patterning device voltage biasing system 10 transitions from a non-contacting arrangement to a contacting arrangement, may be referred to as a contacting step. This contacting step may be part of a larger patterning device MA installation process. Such a patterning device installation process may involve moving the patterning device MA in position relative to the support structure MT; engaging the patterning device clamping mechanism (i.e., a clamping step); and moving the support structure MT and patterning device MA into position within the patterning device environment. Once the support structure MT and patterning device MA have been moved into position, the patterning device voltage biasing system 10 may then transition from the non-contacting arrangement to the contacting arrangement. After the patterning device voltage biasing system 10 has reached the contacting arrangement, the bias voltage can be applied to the patterning surface 40. The provision of the bias voltage to the patterning surface 40 from the voltage source 61 may be performed in a voltage biasing step.

In the transition of the patterning device voltage biasing system 10 from the non-contacting arrangement to the contacting arrangement, components within the patterning device environment 90 should not slide past each other. This is because sliding may cause abrasive wear, which can lead to the generation of contaminant particles within the patterning device environment.

The conductive member 50 may be connected to the voltage source 61 via the conductive member support 53, as is depicted in FIGS. 6 to 8. However, this is not essential, and a separate member (for example, a wire) may be provided to the conductive member 50 such that the conductive member 50 is not connected to the voltage source 61 via the conductive member support 53.

Between the conductive member 50 and the voltage source 61, there may be at least one of a resistor 62, an inductor, a diode, and a switch. Further detail of these components is given below.

The embodiment described above may further comprise a landing portion 57 which can support the patterning device MA in the event that the support structure MT fails. Failure of the support structure MT may involve, for example, loss of power to the support structure MT, resulting in the loss of the attractive force between the support structure MT and the non-patterning surface 41 of the patterning device MA. Without such an attractive force, the patterning device MA may move downwards, away from the patterning device clamp MT.

If the patterning device MA is allowed to downwards unimpeded, it may come into contact with other components, such as other optical components (e.g. mirrors 22, 24, 28) within the lithographic system. This would cause damage to the other optical components, as well as the patterning device MA itself. In the embodiment depicted in FIGS. 6 to 8, this is prevented by the conductive member 50 and a landing portion 57.

If failure of the support structure MT occurs whilst the patterning device voltage biasing system 10 is in the non-contacting arrangement, the patterning device MA may move freely downward until the patterning surface 40 comes into contact with the conductive member 50. If failure of the support structure MT occurs whilst the patterning device voltage biasing system 10 is in the contacting arrangement, the patterning surface 40 is already in contact with the conductive member 50. Once the conductive member 50 and the patterning surface 40 are in contact, the conductive member 50 must be deformed for the patterning device MA to continue to move downward. As the patterning device voltage biasing system 10 is depicted in FIGS. 6 to 8, this deformation would be such that the second end portion 51 of the conductive member 50 moves downward, and the conductive member 50 is rotated in the clockwise direction. This deformation means that a force is applied to the patterning surface 40 in the direction opposite to the deformation of the conductive member 50. That is, the conductive member 50 exerts an upward force on the patterning surface 40. This force is in a direction that is opposite to the movement of the patterning device MA.

As the patterning device MA continues to move downward, the deformation of the conductive member 50 increases, which causes the upward force exerted by the conductive member 50 on the patterning surface 40 to be increased. This may cause the patterning device MA to decelerate.

At some point, the conductive member 50 may be deformed to the extent that it comes into contact with a landing portion 57. A surface of the landing portion 57 may be approximately parallel to the patterning surface 40. The landing portion 57 may be disposed within the patterning device voltage biasing system 10 such that, when the patterning device MA is supported by the support structure MT, the landing portion 57 is below the patterning surface 40. The patterning device MA and the landing portion 57 may overlap in the radial direction, and a radially outer section of the patterning device MA may be located directly below a radially inner section of the landing portion 57. The landing portion 57 may be supported by a landing portion frame 56.

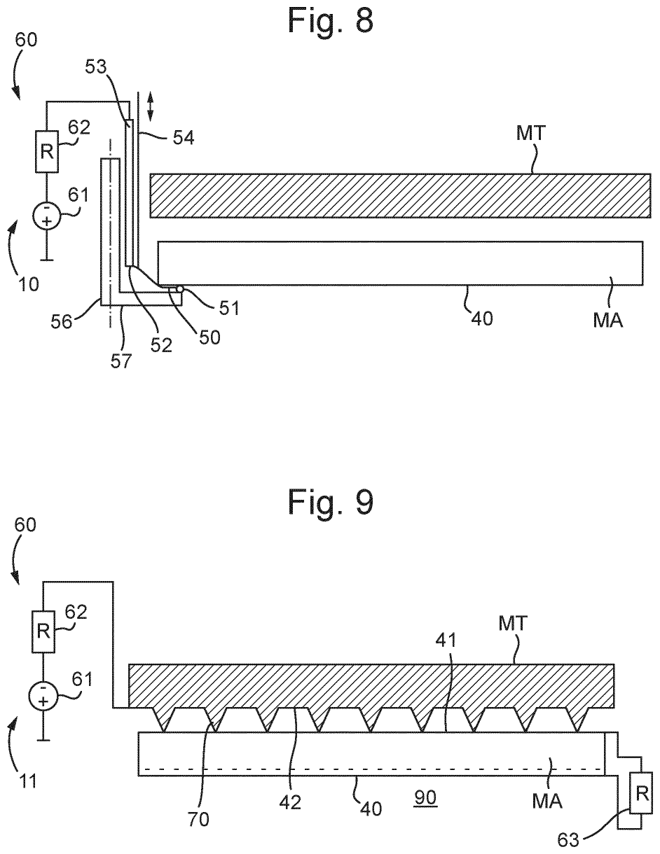

FIG. 8 shows the patterning device voltage biasing system 10 in which the conductive member 50 has made contact with the landing portion 57. This may be considered to be a landed arrangement of the patterning device voltage biasing system 10, in which the conductive member 50 is in a landed position. The landed position is equivalent to the third position defined in the claims. In this position, the second end portion 51 of the conductive member 50 is prevented from deforming further by the landing portion 57. This means that the patterning device MA brought to rest. That is, the patterning device is prevented from moving further downward by the conductive member 50, which is prevented from moving further downward by the landing portion 57. This sequence of events may be referred to as a landing step. By preventing the patterning device MA from moving further downward, damage to components such as optical components 22, 24, 28, which may be located below the patterning device MA, is prevented.

Because the patterning device MA is decelerated gradually by the conductive member 50, a hard landing (in which the patterning device MA is near-instantaneously brought to rest by colliding directly with the landing portion 57) is avoided. This means that the patterning device MA is less likely to be damaged in the event that the support structure MT fails. Further, this functionality is provided by the same component (the conductive member 50) that facilitates the application of a bias voltage to the patterning surface 40 of the patterning device MA. That is, a single component (the conductive member 50) in the patterning device voltage biasing system 10 allows for a bias voltage to be applied to the patterning surface 40 and ensures a soft landing of the patterning device MA onto the landing portion 57 in the event of support structure MT failure.

This mechanism, in which the patterning device MA is provided with a soft landing on a landing portion 57 by the conductive member 50 in the event of a support structure MT failure, is not limited to being implemented in the exact embodiment described above. For example, the mechanism could be implemented where the conductive member 50 is not conductive, and is not configured to apply a bias voltage to the patterning surface 40. That is, a patterning device support system may comprise a landing portion and a deformable member configured in the same way as the landing portion 57 and the conductive member 50 described above, but where the deformable member is not part of a patterning device voltage biasing system.

FIGS. 6 to 8 depict a single landing portion 57. However, there may be a plurality of landing portions 57 distributed evenly around the patterning device MA, such that the patterning device 57 can be supported on all sides in the event that the support structure MT fails. There may be a conductive member 50 corresponding to each of the landing portions 57. This ensures that the landing of the patterning device MA onto the landing portion 57 is soft over the whole circumference of the patterning device MA.

When a plurality of conductive members 50 are provided in the patterning device voltage biasing system 10, the current flowing through the patterning surface 40 can be divided between the plurality of conductive members 50. Consequently, the magnitude of the current at any one point on the patterning surface 40 is reduced. This is beneficial because current flowing though the patterning surface 40 causes the patterning surface 40 to heat up. This can lead to deformation of the patterning surface 40, which can reduce the quality of the pattern projected from the patterning surface 40 to the substrate W.

There may not be the exact same number of landing portions 57 and conductive members 50. For example, there may be more conductive members 50 than landing portions 57, or there may be more landing portions 57 than conducting members 50. As an example, there may be four landing portions 57 (distributed circumferentially around the patterning device MA, each separated by 90 degrees), but only one conductive member 50.

### Second Embodiment

An alternate patterning device voltage biasing system 11 is depicted in FIG. 9. As in the previous embodiment, the patterning device voltage biasing system 11 comprises a patterning device MA with a patterning surface 40 and a voltage source 61. The patterning device voltage biasing system further comprises a support structure MT, which comprises a plurality of burls 70 (e.g. cone-shaped protrusions) on a support surface 42 of the support structure MT that faces a non-patterning surface 41 of the patterning device MA. When the patterning device MA is clamped to the support structure MT, the non-patterning surface 41 is in contact with distal ends of the plurality of burls 70. It is not necessary for each of the plurality of burls to be in contact with the non-patterning surface 41. In general, distal ends of one or more of the plurality of burls 70 may be in contact with the non-patterning surface 41 of the patterning device MA. The non-patterning surface 41 may be referred to as the backside of the patterning device MA.

The non-patterning surface 41 may be conductive. For example, the patterning device MA may comprise a conductive coating, which forms the non-patterning surface 41. The conductive coating may be provided to allow the patterning device MA to be clamped to the support structure MT, which may be an electrostatic clamp.

The patterning device voltage biasing system 11 may be configured such that the non-patterning surface 41 can be electrically connected to the voltage source 61 via the plurality of burls 70. The electrical connection between the voltage source 61 and the plurality of burls 70 may comprise the support surface 42 of the support structure MT being electrically connected to the voltage source 61, the plurality of burls 70 being electrically connected to the support surface 42 of the support structure MT, and the plurality of burls 70 being electrically connected to the non-patterning surface 41 of the patterning device MA. It is not necessary for each of the plurality of burls to be electrically connected to the non-supporting surface 41. In general, one or more of the plurality of burls 70 may be electrically connected to the non-patterning surface 41.

Also, the patterning surface 40 and the non-patterning surface 41 are electrically connected. The electrical connection between the patterning surface 40 and the non-patterning surface 41 may be via a path integral to the patterning device MA itself. Alternatively, the electrical connection between the patterning surface 40 and the non-patterning surface 41 may be via an external path, such as a wire, as is shown in FIG. 9.

With a configuration such as that described above, the bias voltage can be applied to the patterning surface 40 via the support surface 42 of the support structure MT, one or more of the plurality of burls 70, the non-patterning surface 41 of the patterning device MA and an electrical connection between the non-patterning surface 41 and the patterning surface 40.

Between the voltage source 61 and the plurality of burls 70, there may be at least one of a resistor 62, an inductor, a diode, and a switch. Additionally, or alternatively, there may be at least one of a resistor 63, an inductor, a diode, and a switch between the non-patterning surface and the patterning surface. Further detail of these components is given below.

The patterning surface 40 and the non-patterning surface 41 may not be electrically connected to each other. The patterning surface 40 may be electrically isolated, or electrically floating. In such an embodiment, a bias voltage may be applied to the patterning surface 40 capacitively. To capacitively induce a bias voltage on the patterning surface 40, a voltage may be applied to the non-patterning surface 41, i.e. the backside of the patterning device MA, as described above, i.e. via the support surface 42 of the support structure MT and one or more of the plurality of burls 70. When a voltage is applied to the non-patterning surface 41, an electric field may be established between the non-patterning surface 41 and grounded components in the lithographic apparatus. Grounded components may include masking blades (not shown). Masking blades may be provided within the lithographic apparatus adjacent to the patterning surface 40 of the patterning device MA. For example, the masking blades may be provided such that they are displaced from the patterning surface 40 in the z-direction. The masking blades may be configured to selectively mask the patterning device MA from the beam of EUV radiation during exposure. The patterning surface 40 may be located in the electric field. Consequently, when a voltage is applied to the non-patterning surface 41, a bias voltage may be capacitively induced in the patterning surface 40.

### Grounding the Patterning Device

The patterning device voltage biasing system 11 may be configured such that the non-patterning surface 41 can be electrically connected to the ground 67 via the one or more of the plurality of burls 70. In this context, “ground” refers to an electric charge sink which is able to absorb a very large amount of electric charge relative to the amount of charge that may be built up on the patterning device MA during operation of the lithographic apparatus. The exact configuration of the ground is not particularly limited. In some embodiments, the grounding may be provided by the power supply 61 which is used to provide the bias voltage to the patterning surface 41 of the patterning device MA.

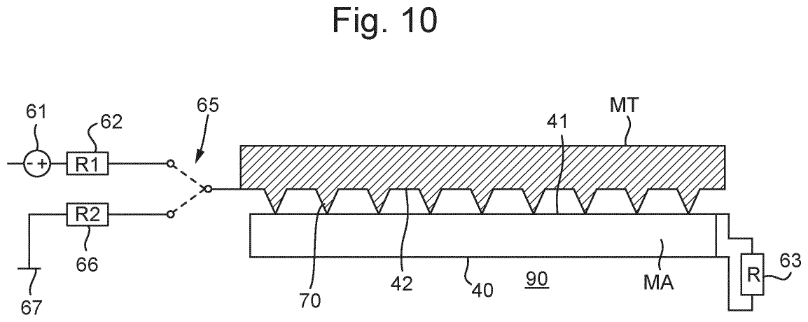

An example of a patterning device voltage biasing system 11 in which the non-patterning surface 41 can be electrically connected to the ground 67 via the one or more of the plurality of burls 70 is depicted in FIG. 10. When the non-patterning surface 41 is electrically connected to the ground 67 via the one or more of the plurality of burls, it may be possible to discharge the patterning device MA (i.e., discharge the non-patterning surface 41 and/or the patterning surface 40).

In the patterning device voltage biasing system 11 depicted in FIG. 10, the non-patterning surface 41 can be connected to the power supply 61 and the ground 67 via the plurality of burls 70. A patterning device voltage biasing system 11 in which the non-patterning surface 41 can be connected to the power supply 61 and the ground 67 via the plurality of burls 70 may comprise a mode-changing switch 65. The mode-changing switch 65 may operate as a two-way switch. That is, the mode-changing switch may be configured such that, at any given time, the non-patterning surface 41 is either connected to (i) the power supply 61 via the one or more of the plurality of burls 70 or (ii) the ground 67 via the one or more of the plurality of burls 70. The patterning device voltage biasing system 11 may be configured such that the non-patterning surface 41 is connected to the power supply 61 via the plurality of burls 70 whilst the lithographic apparatus performs exposure operations, and such that the non-patterning surface 41 is connected to the ground 67 via the plurality of burls 70 during loading and unloading.

Capacitances may exist between the components described above. In particular the capacitance between the supporting surface 42 of the patterning device holder MT and the non-patterning surface 41 of the patterning device MA may be considered to be a variable capacitance, which varies as a function of a gap between the supporting surface 42 of the patterning device holder MT and the non-patterning surface 41 of the patterning device MA.

In a closed system, with no charge able to enter or leave the system, and for a given initial charge state, any variation in the separation between the patterning device MT and the patterning device MA will result in the respective variable capacitances changing. Moreover, this change in capacitance will also result in the potentials across the capacitances changing, possibly significantly, in accordance with the changes in separation. In particular, the relationship Q=CV must be maintained at all times for each capacitance (assuming no charge is injected). Therefore, if a capacitance C is changed, and the amount of charge Q contained in that capacitance is maintained the same, the potential V must change in inverse proportion to the changing capacitance C. This can result in significant potential amplification.

As explained above, charge can accumulate at the isolated surfaces of the patterning device MA, e.g., the patterning surface 40 and the non-patterning surface 41. Residual charge can remain on a clamped patterning device MA once it has been released from the patterning device holder MT. The residual charge that is likely to be present on the patterning device before the patterning device is unclamped from the patterning device support MT may be a negative electrostatic charge on the non-patterning surface 41. This negative electrostatic charge may be caused by the attraction of negative free charges within the plasma to the non-patterning surface 41.

As the unclamped patterning device MA is moved away from the support surface 42, the increasing separation between the support surface 42 and the non-patterning surface 41 can lead to a decrease in capacitance, and an amplification of the potential. That is, given the proportional relationship between charge and potential (i.e. Q=C·V) in a closed system, when the capacitance changes (in inverse proportion to the separation between parallel plates), any reduction in capacitance will result in a proportional increase in potential. Thus, as the patterning device MA and patterning device support MT are separated, it is possible that the potential of the patterning device MA will rise sufficiently to cause electrical breakdown of the hydrogen gas to occur. Such discharge can result in damage to the patterning device MA, the patterning device holder MT and/or particle generation, which can lead to subsequent defects. Consequently, it is preferable that the residual charge on the patterning device MA is small or non-existent before the patterning device MA is unloaded from the patterning device support MT. Similarly, it is preferable that the residual charge on the patterning device MA is small or non-existent before the patterning device MA is loaded onto the patterning device support MT.

Current techniques for discharging the patterning device MA prior to, or during, unloading may involve generating EUV radiation whilst the patterning device MA is unloaded. As explained above, the presence of EUV radiation leads to the existence of plasma in the environment surrounding the patterning device MA. As the separation between the patterning device MA and the patterning device support MT increases, positive ions within the plasma are able to travel to the non-patterning surface 41, thus discharging it. However, the positive ions are not able to reach the non-patterning surface 41 when the separation is small. By the point during the unloading process at which the separation between the patterning device support MT and the non-patterning surface 41 is sufficient for the positive ions within the plasma to be able to reach the non-patterning surface, the potential of the patterning device MA may already have increased significantly (e.g., to 100 s of Vs).

Another technique for reducing the risk of discharge during unloading may involve setting the potential of electrodes in the patterning device support MT such that their average potential is negative during exposure. In doing this, a negative potential can capacitively be induced in the non-patterning surface 41. This negative potential may repel electrons within the plasma during exposure, thus reducing the extent to which negative charge is accumulated on the non-patterning surface during exposure. However, the optimum potential to be induced in the non-patterning surface 41 may vary, and this technique may not be able to fully prevent the accumulation of negative charge on the non-patterning surface 41 in the time before unloading. That is, this technique may not be able to fully solve the problem of electrostatic discharge during the unloading of the patterning device MA.

By connecting the non-patterning surface 41 to the ground 67 via the plurality of burls 70 as depicted in FIG. 10, the non-patterning surface 41 can be discharged effectively before loading and unloading. Consequently, the risk of electrostatic discharge can be reduced.

In the configuration described in relation to FIG. 10, the structure of the mode-changing switch 65 is not particularly limited. The mode-changing switch 65 may comprise electrical or mechanical switching means. The switching of the mode-changing switch 65 may be controlled by a computer program.

As depicted in FIG. 10, the mode-change changing switch 65 is a two-way switch implemented such that a bias voltage can be applied to the patterning device MA or the patterning device MA can be connected to the ground. However, this is not essential, and a bias voltage may be applied to the patterning surface 40 and the patterning device connected to the ground simultaneously. Further detail on how this may be achieved is provided in the “Configuration of the burls” section below.

When a bias voltage may be applied to the patterning surface 40 and the patterning device connected to the ground simultaneously, a voltage supply switch may be provided between the patterning device MA and the voltage supply 61, and a separate grounding switch may be provided between the patterning device MA and the ground 67. However, it may not be necessary to provide a voltage supply switch between the patterning device and the voltage supply 61, and it may not be necessary to provide a grounding switch between the patterning device MA and the ground 67.

A current-limiting component 66 may be disposed in the connection between the plurality of burls 70 and the ground 67. The current-limiting component 66 may be disposed between the mode-changing switch 65 and the ground 67. The current-limiting component 66 may ensure that, when the patterning device MA is discharged to the ground, the current within the patterning device MA (e.g., in the non-patterning surface) is not excessive. The existence of an excessive current within the patterning device MA (e.g., in the non-patterning surface 41) may lead to damage to the patterning device MA. The current-limiting component 66 may be configured such that, when the patterning device MA is discharged to the ground, the current does not exceed 1000 mA, preferably does not exceed 500 mA and further preferably does not exceed 100 mA.

Whilst it may be preferable to limit the current within the patterning device MA during discharge to ensure that the patterning device MA is not damaged, it may also be preferable to ensure that discharge occurs sufficiently quickly for the unloading process not to be delayed. For example, it may be preferable for the discharging of the patterning device MA to take less than 1 s, preferably less than 0.5 s and further preferably less than 0.1 s.

The current-limiting component 66 may include a resistor. A resistance (R₂) of the resistor may be sufficiently large to ensure that the current within the patterning device MA during discharge does not result in damage to the patterning device MA. Also, the resistance (R₂) of the resistor may be sufficiently small to ensure that the time taken for the patterning device MA to be discharged does not result in delays to the unloading process. For example, the resistance (R₂) may be greater than 1Ω, preferably greater than 10Ω and further preferably greater than 200Ω. Desirably the resistance may be less than 10 kΩ, preferably less than 1 kΩ, and further preferably less than 400Ω. If more than one resistor 66 is provided between the patterning surface 40 and the ground 67, the resistance values specified above may apply to the combined resistance (i.e. the effective resistance) of the combination of the resistors. That is, the resistance values specified above may apply to the total resistance between the patterning surface 40 and the ground.

Alternatively or in addition, the current-limiting component may include an inductor having an inductance. In the case that an inductor is provided, the inductance of the inductor may be greater than 1 μH, preferably greater than 1 mH, and further preferably greater than 5 mH. The inductance of the inductor may be less than 100 mH, preferably less than 50 mH, and further preferably less than 10 mH. For example, the inductance of the inductor may be approximately 10 mH. If more than one inductor is provided between the patterning surface 40 and the ground 67, the inductance values specified above may apply to the combined inductance (i.e. the effective inductance) of the combination of inductors. That is, the inductance values specified above may apply to the total inductance between the patterning surface 40 and the ground 67.

The patterning device voltage biasing system 11 may be configured such that the non-patterning surface 41 is connected to the ground 67 via the plurality of burls 70 before the patterning device MA is unloaded from the patterning device support MT (i.e., before the patterning device MA begins to be separated from the patterning device support MT). In doing this, it can be ensured that the patterning device MA is substantially fully discharged before the distance between the patterning device MA and the patterning device support MT increases. Consequently, increases in the potential of the patterning device MA during unloading can be avoided. The patterning device MA may remain connected to the ground 67 whilst the unloading procedure is performed.

The patterning device voltage biasing system 11 may be configured such that the non-patterning surface 41 is connected to the ground 67 via the plurality of burls 70 before the patterning device MA is loaded onto the patterning device support MT. The patterning device MA may remain connected to the ground 67 throughout the loading process. The function of the mode-changing switch may change once the patterning device MA has been fully loaded onto the patterning device support MT. That is, once the patterning device MA has been fully loaded onto the patterning device support MT, the non-patterning surface 41 may be connected to the power supply 61 so that the bias voltage can be applied.

Discharging of the patterning device MA via the one or more of the plurality of burls 70 has been described above in relation to the second embodiment, in which a bias voltage may be applied to a patterning surface 41 of the patterning device MA via the one or more of the plurality of burls 70. However, discharging of the patterning device MA via the one or more of the plurality of burls 70 may not be limited to being implemented in such an embodiment. For instance, discharging of the patterning device MA may be implemented in a configuration such as the first embodiment described above. Further, in some embodiments, discharging of the patterning device MA may be performed via a conductive member, such as the conductive member 50 described in relation to the first embodiment.

The following sections outlines a number of other features that may be implemented in either the first embodiment or second embodiment, or any other appropriate method for the application of a bias voltage to the patterning surface 40 of a patterning device MA.

### Limiting the Current Through the Patterning Device During an EUV Pulse

In some embodiments, the bias voltage may be applied continuously throughout a sequence of exposure operations that are performed by the lithographic apparatus. That is, the same bias voltage may be provided to the patterning surface 40 when the EUV pulse is off and t when the EUV pulse is on. For example, a negative bias voltage may be provided to the patterning surface 40 when the EUV pulse is off, and the same negative bias voltage may be provided to the patterning surface 40 when the EUV pulse is on.

However, during each pulse of EUV radiation, a very large current may be drawn from the voltage source 61. The size of this current may be large enough to damage components such as the voltage source 61. Also, when very large currents are provided to the patterning device MA, the patterning device MA may heat up. This can cause the patterning device MA to deform, which can cause errors in the pattern projected from the patterning device MA onto the substrate W. Consequently, it may be preferable that the current through the patterning device is controlled or limited throughout the operation of the lithographic apparatus or at least during each pulse of radiation. To achieve this, the patterning surface 40 may be connected to the voltage source 61 via at least one of an resistor 62, 63, an inductor, a diode, or a switch.

In the case that a resistor 62, 63 is provided in the path between the voltage source 61 and the patterning surface 40, the size of the current drawn from the voltage source 61 during pulses of EUV radiation is limited by the additional resistance within the circuit. The resistance of the resistor 62, 63 may be greater than 1Ω, preferably greater than 10Ω and further preferably greater than 200Ω. Desirably the resistance may be less than 10 kΩ, preferably less than 1 kΩ, and further preferably less than 400Ω. If more than one resistor 62, 63 is provided between the patterning surface 40 and the voltage source 61, the resistance values specified above may apply to the combined resistance (i.e. the effective resistance) of the combination of the resistors. That is, the resistance values specified above may apply to the total resistance between the voltage source 61 and the patterning surface 40. In this way an RC characteristic of about 1 μs for the circuit can be achieved. It is desirable that the RC characteristic is less than about 10 μs.

An inductor may be provided in the path between the voltage source 61 and the patterning surface 40 instead or in addition to a resistor. In the case that an inductor is provided the inductance of the inductor may be greater than 1 μH, preferably greater than 1 mH, and further preferably greater than 5 mH. The inductance of the inductor may be less than 100 mH, preferably less than 50 mH, and further preferably less than 10 mH. For example, the inductance of the inductor may be approximately 10 mH. If more than one inductor is provided between the patterning surface 40 and the voltage source 61, the inductance values specified above may apply to the combined inductance (i.e. the effective inductance) of the combination of inductors. That is, the inductance values specified above may apply to the total inductance between the voltage source 61 and the patterning surface 40.

Alternatively, a switch may be provided between the voltage source 61 and the patterning surface 40. The switch may be referred to as a timing switch. The patterning device voltage biasing system may be configured such that the timing switch is open whilst a pulse of EUV radiation is generated, and the timing switch is closed when a pulse of EUV radiation is not generated. That is, the bias voltage may be provided to the patterning surface 40 when the EUV pulse is off, but the bias voltage may not be provided to the patterning surface 40 when the EUV pulse is on. In this way, no current can be drawn by the patterning device MA when a pulse of EUV radiation is generated, which means that surges of current from the voltage source 61 to the patterning surface 40 when the EUV pulse is generated are prevented.

To be able to provide this function, the timing switch may be capable of operating at the same frequency as the frequency of the EUV pulse. For example, the timing switch may be capable of operating at a frequency that is greater than 49 kHz, preferably greater than 59 kHz, and further preferably greater than 99 kHz. For example, the timing switch may be capable of operating at 100 kHz. The timing switch may be configured such that it is controlled by a signal from another component within the lithographic apparatus 100 corresponding to the EUV pulse being turned on and off. That is, the controlling of the timing switch to be open or closed may be synchronized with the switching on and off of the pulse of EUV radiation.

This scenario, in which the bias voltage is cyclically switched on and off is different to the application of bias voltage shown in FIGS. 4A-5B. If the bias voltage is not provided to the patterning surface 40 whilst the pulse of EUV radiation is on, the increase in the voltage of the patterning surface 40 during the EUV pulse may be larger than is shown in FIG. 4B. However, because the bias voltage can be provided to the patterning surface 40 immediately after the pulse of EUV radiation has been switched off, the voltage of the patterning surface 40 will quickly decrease to become negative again. Therefore, a voltage biasing system in which the bias voltage is not provided to the patterning surface 40 whilst the pulse of EUV radiation is on would still have the effect that, over time, the distance between the contaminant particles P and the patterning surface 40 increases.

The resistor and/or inductor may be provided within the patterning device or within an external circuit. For example, the resistor and/or inductor may be provided closer to the voltage source than the timing switch.

### Positive Bias Voltage

The embodiments described above have referred to the application of a negative bias voltage to the patterning surface 40, so that negatively charged contaminant particles P are repelled from the patterning surface 40. However, there may be circumstances which cause contaminant particles within the patterning device environment to become positively charged. In this case, a positive bias voltage may be applied to the patterning surface 40, such that the positively charged contaminant particles P are repelled by the positively charged patterning surface 40.

Embodiments also include applying a variable bias voltage.

In particular, embodiments include applying a positive voltage whilst the EUV pulse is on and a negative bias voltage when the EUV pulse is off.

As explained above, EUV-induced emission of electrons through the photoelectric effect from the patterning surface 40 contributes to the deposition of contaminant particles P on the patterning surface (and therefore imaging errors). This is because: (i) the emission of electrons causes the patterning surface 40 to become positively charged (and be brought to a positive potential), thus attracting negatively charged contaminant particles; and (ii) the emission of electrons adds additional electrons to the plasma within the patterning device environment 90, which may increase the number of contaminant particles that become negatively charged or the magnitudes of the negative charges on the contaminant particles P. Consequently, by reducing or preventing the emission of electrons whilst the patterning surface 40 is exposed to EUV radiation, fewer contaminant particles P may be deposited on the patterning surface 40.

By inducing a positive potential in the patterning surface 40 whilst the patterning surface 40 is exposed to EUV radiation, the emission of electrons from the patterning surface can be reduced. Consequently, the patterning surface 40 may become positively charged to a lesser extent, and may contribute less electrons to the plasma in the patterning device environment 90.

The magnitude of the positive bias potential applied to the patterning surface 40 may be sufficient to prevent the emission of electrons by the photoelectric effect. That is, the magnitude of the positive bias may be such that the positive potential induced at the patterning surface 40 is greater than a stopping potential (Vₛₜₒₚ). The maximum kinetic energy of an electron emitted though photoemission is given by Equation (2), where h is the Planck constant (4.14×10⁻¹⁵ eVs), f is the frequency of the radiation, and φ is the work function of the material (i.e., the minimum energy required to cause emission of an electron from a surface). The work function is a property of the material of the surface from which electrons are emitted.

$${E}_{kmax} = hf - φ \qquad ( 2 )$$

Photoemission cannot occur when the energy supplied to the electrons by an electric field arising from the positive potential induced at the patterning surface 40 is greater than the maximum possible kinetic energy of the emitted electrons. Thus, the stopping potential can be defined as in Equation (3).

$${eV}_{stop} = hf - φ \qquad ( 3 )$$

In EUV lithography, the wavelength of radiation may be approximately 13.5 nm. Thus, the photon energy of a photon within a beam of EUV radiation may be approximately 92 eV. The work function of the patterning surface 40 may be dependent on the material from which the patterning surface 40 is formed. In general, the work function may be between 2 eV and 7 eV. If the work function is 7 eV or less, it may be preferable for the potential induced on the patterning surface 40 to be approximately 85 V or greater to substantially suppress photoemission. If the work function is 2 eV or less, it may be preferable for the potential induced on the patterning surface 40 to be approximately 90 V or greater to substantially suppress photoemission. A majority of electrons released from the patterning surface 40 upon irradiation with EUV radiation generally have a low energy, e.g., an energy that is less than 10 eV. This may be because EUV photons are absorbed at effective depth of approximately 10 to 100 nm. As electrons which have absorbed an EUV photon propagate to the vacuum interface from the absorption position to the surface, they may lose energy. Considering this, to significantly suppress the emission of electrons through the photoelectric effect, it may be sufficient to apply a positive bias voltage which is greater than +50V. In this case, the positive bias voltage may be less than 100 V to reduce the risk of discharge. To moderately suppress the emission of electrons through the photoelectric effect, it may be sufficient to apply a positive bias that is greater than 5 V. In this case, the positive bias voltage may be less than 50 V to further reduce the extent to which the positive bias voltage applied to the patterning surface leads to physically sputtering of ions onto grounded surfaces, such as the masking blades. Considering this, it may be preferable for the positive bias voltage to be greater than 5 V and less than 50 V.

To apply a negative bias voltage to the patterning surface 40 when the EUV pulse is off, and a positive bias voltage may be provided to the patterning surface 40 when the EUV pulse is on, the patterning device voltage biasing system may be synchronized with the pulses of EUV radiation generated by the lithographic apparatus. The means by which the polarity of the bias voltage is switched is not particularly limited.

A further advantage of bringing the patterning surface 40 to a positive voltage whilst the EUV radiation is present in the lithographic apparatus is that positive ions (e.g. hydrogen ions) which are formed by EUV-induced ionization may be repelled from the patterning surface. If positive ions collide with the patterning surface 40, damage may be caused to the patterning surface 40. Consequently, by bringing the patterning surface 40 to a positive bias voltage, fewer positive ions may collide with the patterning surface 40, and the positive ions that do collide with the patterning surface 40 may have a lower energy. This means that the damage caused to the patterning surface 40 by the ions is decreased.

The positive bias voltage may be applied to the patterning surface using any appropriate means. The positive bias voltage may be applied through the same means that are used to apply the negative bias voltage. For example, the positive bias voltage may be applied as described in relation to the First and Second embodiments.

Alternatively, the patterning surface 40 may be brought to a positive voltage by limiting the current in the circuit which provides the negative bias voltage to the patterning surface 40. For example, the current in the circuit which provides the bias voltage may be limited such that the current in the circuit which provides the bias voltage is less than the current which corresponds to the emission of electrons from the patterning surface 40 through the photoelectric effect. Consequently, whilst the patterning surface 40 is exposed to EUV radiation, the voltage of the patterning surface may be defined by the current which corresponds to the emission of electrons from the patterning surface 40 through the photoelectric effect. This means that the patterning surface 40 may be brought to a positive voltage, even if the power supply and the corresponding circuitry continue to operate in the same way as when a negative bias potential is applied to the patterning surface 40.

The current in the circuit which provides the bias voltage may be limited may be limited in any suitable way. The current in the circuit which provides the bias voltage may be limited as described above in the “Limiting the current through the patterning device during an EUV pulse” section. The extent to which the current in the circuit which provides the bias voltage is limited may be changed over time, and/or may be controllable. For example, the current may be limited more whilst the patterning surface 40 is exposed to a pulse of EUV radiation relative to when the patterning surface 40 is not exposed to EUV radiation. This may be to allow the patterning surface 40 to be brought to a positive voltage when the patterning surface 40 is exposed to EUV radiation.

### Configuration of the Burls

As described above, the non-patterning surface 41 may be grounded via one or more of the plurality of burls 70. The one or more of the plurality of burls may comprise substantially all of the burls on the support structure 70.

It may be preferable for the non-patterning surface 41 to be grounded through a small proportion of the burls 70 on the support structure. These burls may be referred to as grounding burls. Grounding burls may make up less than 10%, preferably less than 5% and further preferably less than 1% of the total burls 70 on the support structure MT. Grounding the non-patterning device through a small proportion of the burls 70 may allow the non-patterning surface to be effectively discharged, without compromising the clamping of the patterning device MA to the support structure MT.

The grounding burls may be located in a border region of the support structure. For example, grounding burls may be in an outermost ring of burls 70. The grounding burls may be located in one or more corners of the support structure MT. Locating the grounding burls in such locations may reduce the effect that the grounding of the burls 70 has on the clamping of the patterning device MA to the support structure MT, or limit the regions in which the clamping of the patterning device MA to the support structure MT to regions which are not critical to the quality of the image projected from the patterning device MA.

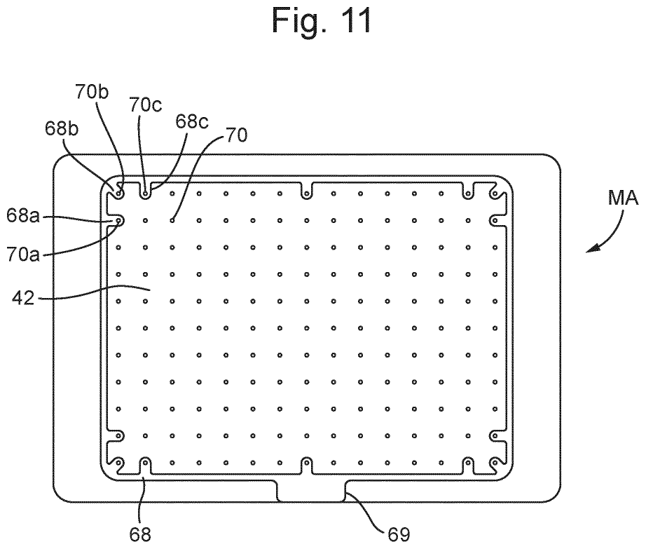

FIG. 11 depicts a plan view of a support structure MT in accordance with an embodiment of the present invention. The surface of the support structure MT which is visible is the support surface 42. As depicted in FIG. 11, the support structure is rectangular, but the present invention is not limited thereto. The support structure MT comprises a plurality of burls 70 formed on the support surface 42, as have been described previously. The support structure MT further comprises a conductive track 68 formed on the support surface 42. The conductive track 68 may be formed around a perimeter of the support surface 42. The conductive track 68 may be formed outward of the burls 70.

The conductive track 68 may be connected to an interface 69. The interface 69 may allow the conductive track 68 to be connected to external circuitry. The external circuitry may connect the interface to the ground 67.

Of the plurality of burls 70, the support structure MT may comprise a plurality of grounding burls (e.g. burls 70a, 70b, 70c). The grounding burls 70a, 70b, 70c may be coated with a conductive material. The conductive material may be the same as the material which forms the conductive track. The grounding burls 70a, 70b, 70c may be electrically connected to the conductive track 68. The grounding burls 70a, 70b, 70c may be electrically connected to the conductive track 68 via one or more extensions of the conductive track (e.g. extensions 68a, 68b, 68c). As depicted in FIG. 11, each grounding burl 70a, 70b, 70c is provided with an extension 68a, 68b, 68c. The extensions 68a, 68b, 68c may extend inward from the conductive track 68 to the grounding burl 70a, 70b, 70c. In some embodiments, one extension 68a, 68b, 68c may connect a plurality of grounding burls 70a, 70b, 70c to the conductive track 68.

The conductive track 68 may be formed of any suitable conductive material. For example, the conductive track may be formed of titanium nitride (TiN). The conductive material may be deposited onto the support surface 42 using any suitable technique. After deposition of the conductive material, the conductive material may be patterned to form the shape of the conductive track 68, the extension 68a, 68b, 68c and the coatings for the burls 70.

The bias voltage may be applied in the same way. That is, the bias voltage may be applied via a plurality of bias burls (not shown). The bias burls may be connected to another conductive track via one or more extensions. The bias burls may be different to the grounding burls 68a, 68b, 68c.

In some embodiments, the bias burls may be the same as the grounding burls. In this case, the mode-changing switch may be provided between (i) the conductive track and (ii) the voltage source and the ground. Thus, a single subset of the burls may be able to apply the bias voltage and the connection to the ground, depending on the setting of the mode-changing switch.

A configuration such as that described above may allow for the non-patterning surface 41 to be continuously grounded, irrespective of whether or not a bias voltage is applied.

### Configuration of the Patterning Device

In this section, further details of how a bias voltage may be applied to the patterning surface 40 of the patterning device MA through a physical connection are provided.

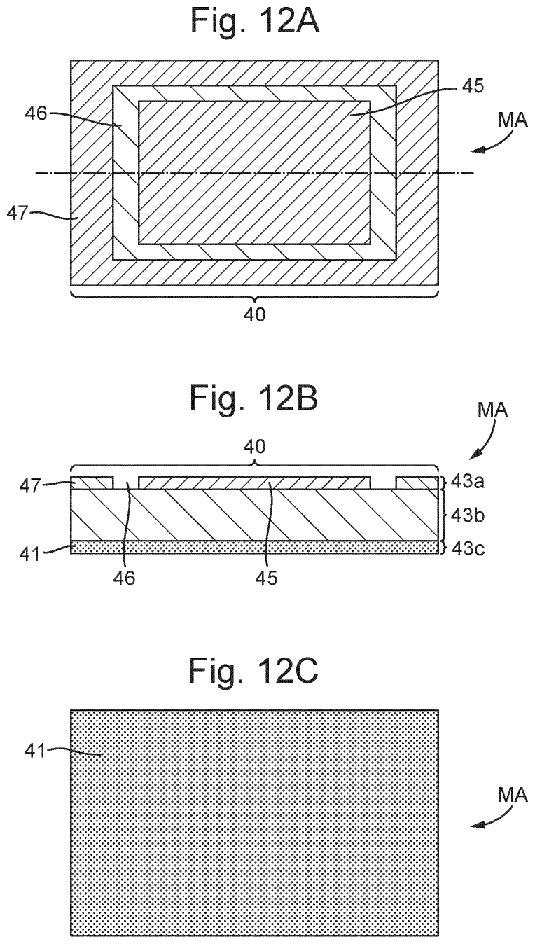

FIGS. 12A-12C depict a patterning device MA. The patterning device MA depicted in FIGS. 12A-12C may be a conventional patterning device MA. The patterning device MA depicted in FIGS. 12A-12C may be implemented in some embodiments of the present invention. FIG. 12A depicts a plan view of the patterning device MA, showing the patterning surface 40. FIG. 12B depicts a cross-sectional view of the patterning device MA. The cross-section may be taken the centerline depicted in FIG. 12A. FIG. 12C depicts a plan view of the patterning device MA, showing the non-patterning surface 41, i.e. the backside of the patterning device MA.

As shown in FIG. 12B, the patterning device may comprise a plurality of portions 43a, 43b, 43c in a layered arrangement. A reflective portion 43a may be conductive. The reflective portion 43a may comprise a multi-layer stack (not shown). The multi-layer stack may be a distributed Bragg reflector. The multi-layer stack may comprising alternating layers of material. For example, the multi-layer stack may comprise alternating layers of molybdenum (Mo) and silicon (Si), though the present invention may not be limited thereto. One or more of the materials in the multi-layer stack may be conductive. The reflective portion 43a may further comprise a capping layer (not shown). The capping layer may be formed of a conductive material. For example, the capping layer may be formed from a material substantially comprising ruthenium (Ru).

The reflective portion 43a may be formed on a first surface of a core portion 43b. The core portion 43b may be a substrate for the reflective portion 43a. The core portion 43b may be formed of an ultra-low expansion (ULE) glass. For example, the core portion 43b may be formed of a material substantially comprising a lithium-aluminosilicate glass-ceramic (e.g. ZERODUR®). A conductive portion 43c may be formed on a second surface of the core portion 43b.

The second surface of the core portion 43b may be opposite the first surface of the core portion 43b. The conductive portion 43c may cover substantially all of the second surface of the core layer 43b.

The patterning surface 40 may be the surface that faces away from the support structure of the patterning device. The non-patterning surface 41 may be the surface that faces towards the support structure of the patterning device.

The patterning surface 40 depicted in FIGS. 12A-12C comprises a patterning area 45, a border area 46 and a perimeter area 47. The patterning area 45 may be located in a central region of the patterning surface 40. In the patterning area 45, the reflective portion 43a is provided on the core portion 43b. The patterning area 45 may be the region of the patterning surface 40 that is configured to be exposed to EUV radiation and impart a pattern thereto.

The border area 46 may surround the patterning area 45. In the border area 46, the reflective portion 43a may not be provided on the core portion 43b. That is, in the border area 46, the core layer 43b (and, specifically, the first surface of the core layer 43b) may be exposed. The border area may not be reflective to EUV radiation. The border area 46 may be provided to avoid the undesired exposure of regions surrounding an image region on the substrate W that is being exposed. In some embodiments, the reflective portion 43a may be present in the border area 46, but with a reduced height.

The perimeter area 47 may surround the border area 46. In the perimeter area 47, the reflective portion 43a is provided on the core portion 43b. Of the areas making up the patterning surface 40, the patterning area 45 and the perimeter area 47 may be conductive, but the border area 46 may be a substantial electrical insulator such that the border area 46 does not provide a direct electrical path between the perimeter area 47 and the patterning area 45.

In the patterning device MA depicted in FIGS. 12A-12C, the conductive layer 43c (and the non-patterning surface 41) may be electrically isolated from the reflective layer 43a (and the patterning surface 40). Consequently, to apply a bias voltage to the reflective portion 43a (and the patterning surface 40) of the patterning device MA depicted in FIGS. 12A-12C, an electrical connection could be made using a conductive member 50, as described in relation to the first embodiment. Additionally or alternatively, a bias voltage could be applied to the reflective portion 43a (and the patterning surface 40) capacitively by applying a voltage to the conductive portion 43c (and the non-patterning surface 41), e.g. via the burls 70.

To manufacture the patterning device depicted in FIGS. 12A-12C, the reflective portion 43a may be formed on substantially all of the first surface of the core portion 43b. Parts of the reflective portion 43a may then be selectively removed. For example, parts of the reflective portion 43a corresponding to the border area 46 may be removed. This may be such that the first surface of the core portion 43b is exposed in the border area. Alternatively, this may be such that the height of the reflective portion 43a above the first surface of the core portion 43b is reduced. This may leave the patterning area 45, the border area 46 and the perimeter area 47, as described above. Parts of the reflective portion 43a may be removed by a process involving lithography and etching.

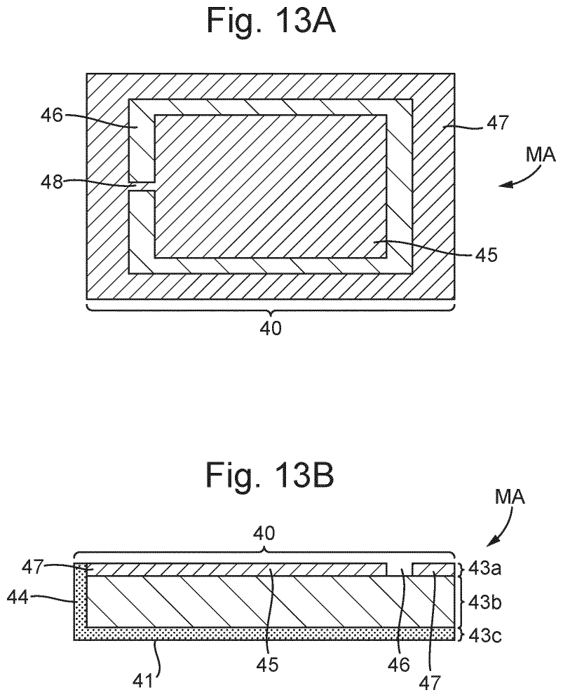

FIGS. 13A and 13B depict an alternative patterning device MA according to an embodiment. FIG. 13A depicts a plan view of the patterning device MA, showing the patterning surface 40. FIG. 13B depicts a cross-sectional view of the patterning device MA. The cross-sectional view may be the same view as that depicted in FIG. 12B. The patterning device MA depicted in FIGS. 13A and 13B may be similar to the patterning device MA depicted in FIGS. 12A-12C, except as described below.

In the patterning device MA depicted in FIGS. 13A and 13B, the conductive portion 43b may be provided to one or more edges of the patterning device MA. The extended section of the conductive portion 43b may be referred to as a conductive edge 44. The conductive edge 44 may extend from the reflective portion 43a to the conductive portion 43c. The conductive edge 44 may substantially cover an edge of the core portion 43b. The conductive edge 44 may electrically connect the conductive portion 43c and the reflective portion 43a. That is, the conductive edge 44 may connect the non-patterning surface 41 and the patterning surface 40. Specifically, the conductive edge 44 may electrically connect the conductive portion 43c and the reflective portion 43a in the perimeter area 47.

The patterning device MA may further comprise a bridge 48. The bridge 48 may electrically connect the perimeter area 47 of the reflective portion 43a and the patterning area 45 of the reflective portion 43a. The bridge 48 may span the border area 46. The bridge 48 may be a region within the border area 47 in which the reflective layer 43a is provided to electrically connect the perimeter area 47 and the patterning area 45. The bridge may be formed by adjusting the parts of the reflective portion 43a that are removed when the border area 46 is formed. Specifically, when parts of the reflective portion 43a are removed to form the border area 46, the part of the reflective portion 43a corresponding to the bridge 48 may not be removed. This means that the bridge 48 may be formed in the reflective portion 43a, and thus be formed of the same material as the patterning area 45 and the perimeter area 47 of the reflective portion 43a. The bridge 48 may additionally be provided with EUV absorbing layer. The bridge 48 may comprise a plurality of strips connecting the patterning area 45 and the perimeter area 47. A width of each strip may be less than the resolution of the lithographic apparatus. For example, a width of each strip may be less than 40 nm, preferably less than 20 nm, and further preferably less than 10 nm. This may ensure that bridge 48 does not deteriorate the pattern transferred from the patterning area 45 towards the substrate W.

With the configuration depicted in FIGS. 13A-13B, a bias voltage may be applied to the perimeter area 47 of the reflective portion 43a from a voltage supply 61 via: the support surface 42 of the support structure MT; one or more burls 70 on the support surface 42 of the support structure MT; the conductive layer 43c of the patterning device MA; the conductive edge 44. The bias voltage may be applied to the patterning area 45 of the patterning device through the same path with the addition of the bridge 48. In doing this, the bias voltage is applied to the patterning surface 40.

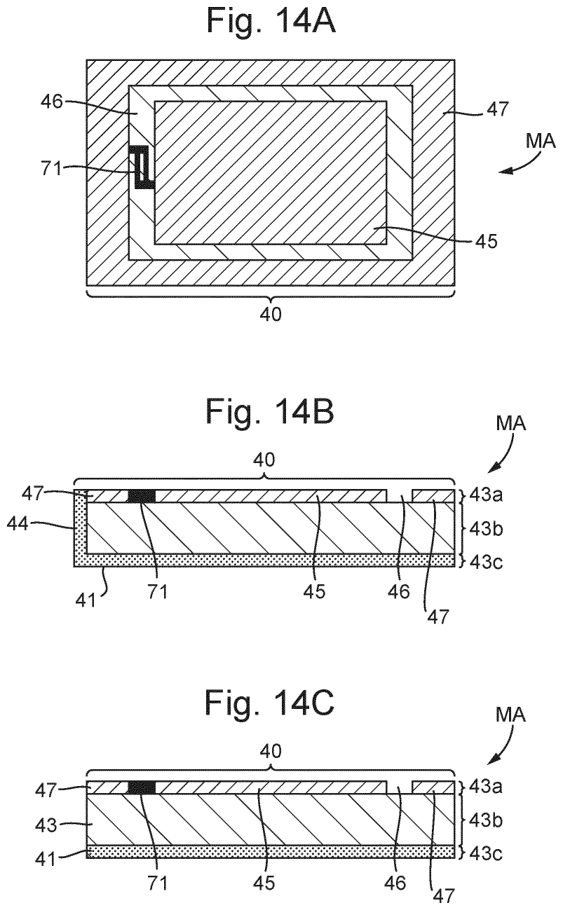

With a patterning device MA such as the patterning device MA depicted in FIGS. 13A and 13B, current-limiting components, such as resistors or inductors, could be implemented between the support surface 42 of the support structure MT and the voltage source 61. FIGS. 14-18 depict embodiments in which current-limiting components are integrated within the patterning device MA. The current-limiting components may be features formed in the reflective portion 43a and the conductive portion 43c. The current-limiting components may be formed during the process in which parts of the reflective portion 43a are removed (e.g, etched away) to form, for example, the border area 46. Specifically, when parts of the reflective portion 43a are removed, parts of the conductive portion which are required to form the current-limiting components are not removed. This means that the current-limiting component 71 may be formed in the reflective portion 43a, and thus be formed of the same material as the patterning area 45 and the perimeter area 47 of the reflective portion 43a.

FIG. 14A depicts a plan view of a patterning surface 40 of a patterning device MA according to an embodiment in which a current-limiting component 71 is integrated in the border area 46. The current-limiting component 71 may be electrically connected to the reflective portion 43a in the perimeter area 47 and the reflective portion 43a in the patterning area 45. The size of features which make up the current-limiting component 71 may be such that the features are not imaged onto a substrate. That is, the size of features which make up the current-limiting component 71 may be less than the critical dimension of the lithographic apparatus. For example, the dimensions of the features of the features which make up the current-limiting component 71 may be less than approximately 40 nm, preferably less than 20 nm and further preferably less than 10 nm. This may apply to any components or features formed within the border area 46 of the reflective portion 43a.

FIG. 14B depicts a cross-sectional view of a first implementation of a patterning device MA which has a current-limiting component 71 integrated in the border area 46 of the reflective portion 43a, as depicted in FIG. 14A. The patterning device MA depicted in FIG. 14B comprises a conductive edge 44. Consequently, a bias voltage may be applied to the reflective portion 43a in the patterning area 45 via the non-patterning surface 41, the conductive edge 44, the reflective portion 43a in the perimeter area 47 and the current-limiting component 71. In this way, the current in the patterning area 45 of the reflective portion 43a may be limited. A current-limiting component positioned in this way may not limit the current in the perimeter area 47 of the reflective portion 43a. Limiting the current in the perimeter area 47 of the reflective portion 43a may be less important, because deformation in the perimeter area 47 of the reflective portion 43a will not lead to imaging errors.

FIG. 14C depicts a cross-sectional view of a second implementation of the patterning device MA according to an embodiment which has a current-limiting component 71 integrated in the border area 46 of the reflective portion 43a as depicted in FIG. 14A. The patterning device MA may have the same plan view as that shown in FIG. 14A. The patterning device MA depicted in FIG. 14C is similar to the patterning device MA depicted in FIGS. 12A-12C in that the patterning device depicted in FIG. 14C does not comprise a conductive edge 44. That is, in the patterning device MA depicted in FIG. 14C, reflective portion 43a may be isolated from the conductive portion 43c. Thus, to apply a bias voltage to the patterning surface 40 (and, specifically, to the patterning area 45 of the patterning surface 40), a conductive member 50 may contact the reflective portion 43a. Specifically, the conductive member 50 may contact the perimeter area 47 of the reflective portion 43a. Thus, the patterning area 45 of the patterning surface 40 may be electrically connected to the voltage supply 61 via the current-limiting component 71.

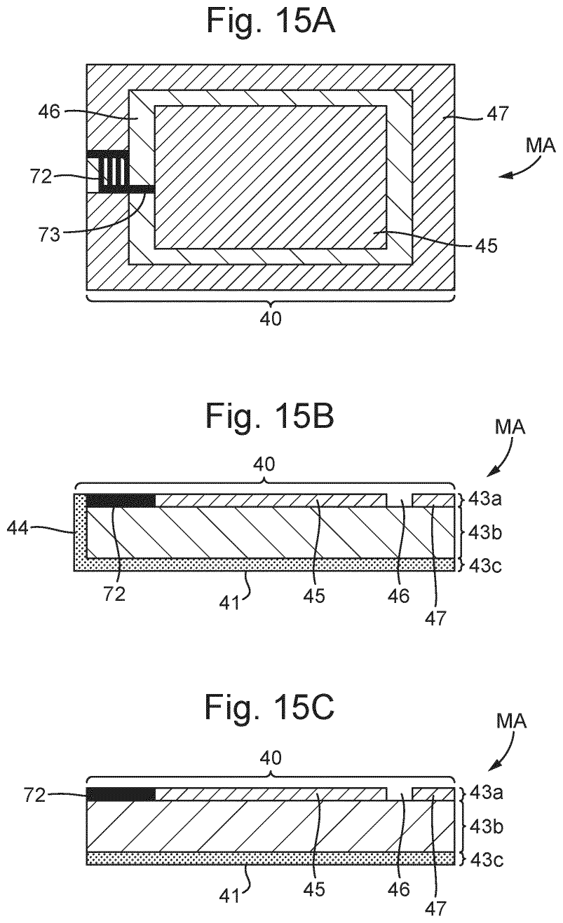

FIG. 15A depicts a plan view of a patterning surface 40 of a patterning device MA that is similar to the patterning device depicted in FIG. 14A, except that the current-limiting component 72 is formed in the perimeter area 47 of the reflective portion 43a, rather than in the border area 46 of the reflective portion 43a. To form the current-limiting component 72, additional parts of the reflective portion 43a may be removed from the perimeter area 47 of the reflective portion 43a. A bridge portion 73 may extend across the border area 46 to electrically connect the current-limiting portion 72 to the patterning area 45 of the reflective portion 43a.

FIG. 15B depicts a cross-sectional view of a first implementation of the patterning device MA which has a current-liming component 72 integrated in the perimeter area 47 of the reflective portion 43a as depicted in FIG. 15A. In the patterning device MA depicted in FIG. 15C, the reflective portion 43a may be electrically connected to the conductive portion 43c (as in the patterning device depicted in FIG. 14B).

FIG. 15C depicts a cross-sectional view of a second implementation of a patterning device MA which has a current-limiting component 72 integrated in the perimeter area 47 of the reflective portion 43a as depicted in FIG. 15A. In the patterning device MA depicted in FIG. 15C, the reflective portion 43a may not be electrically connected to the conductive portion 43c (as in the patterning device depicted in FIG. 14C).

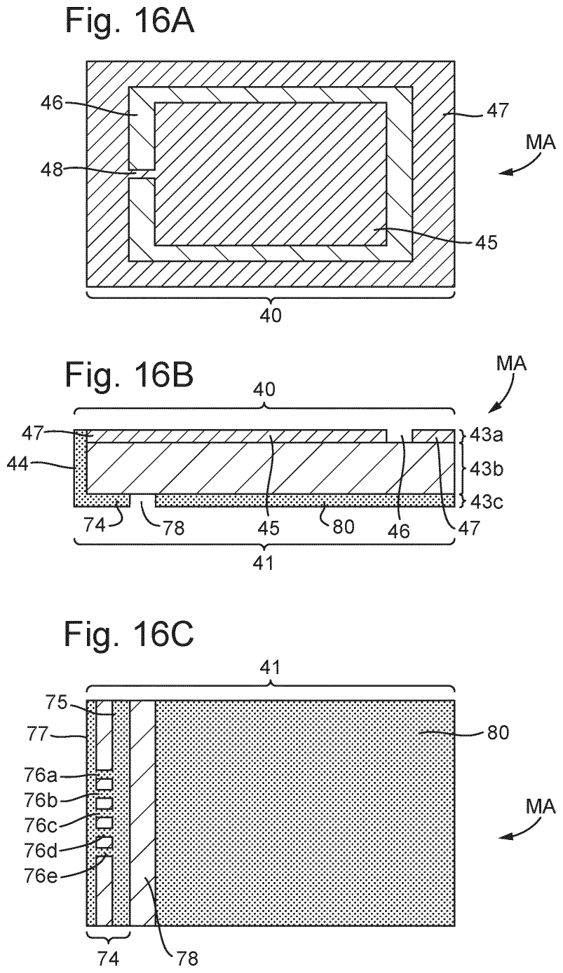

FIGS. 16A-16C depict a patterning device MA in which a current-limiting component 74 is formed in the conductive portion 43c of the patterning device MA. FIG. 16A depicts a plan view of the patterning surface 40 of the patterning device; FIG. 16B depicts a cross-sectional view of the patterning device MA; and FIG. 16C depicts a plan view of the non-patterning surface 41 of the patterning device MA.

As shown in FIG. 16A, the patterning device MA may comprise a bridge 48 such that the perimeter area 46 of the reflective portion 43a is electrically connected to the patterning area 45 of the reflective portion 43a. The patterning device MA may further comprise a conductive edge 44.

The conductive portion 43c is patterned. That is, parts of the conductive portion are not present, such that the core portion 43b is exposed. Specifically, parts of the conductive portion 43c may be removed to form the current-limiting component 74. The removal of material may be performed through a process involving lithography and etching.

The removal of material from the conductive portion 43c may be performed in the proximity of one edge of the conductive portion 43c. In the schematic depiction in FIG. 16C, this is the left edge. The majority of the conductive portion 43c may be unaffected by the removal of material from the conductive portion 43c. That is, the unaffected area 80 may make up more than 90% of the non-patterning surface, and preferably more than 99% of the patterning surface. This may be to ensure that the presence of the current-limiting component 74 within the conductive portion 43c does not significantly impact the ability of the non-patterning surface 41 to be clamped to the support structure MT.

In an embodiment such as the embodiment described above, a current limiting component may be provided in the conductive coating, or an insulating strip may be provided in the clamping coating and a current-limiting component provided in the external circuit.

An insulating strip 78 may separate the unaffected area 80 from the current-limiting component 74. The insulating strip may be an area from which the conductive portion 43c has been removed to leave the second surface of the core portion 43b exposed.

The current-limiting component 74 may comprise an input area 75, an output area 77 and one or more current-limiting features 76a-76e. Each of the input area 75, the output area 77 and the one or more current-limiting features 76a-76e may be formed from the conductive portion 43c. That is, the input area 75, the output area 77 and the one or more current-limiting features 76a-76e may be defined by the removal of the conductive portion 43c from around the input area 75, the output area 77 and the one or more current-limiting features 76a-76e. The one or more current-limiting features 76a-76e may electrically connect the input area 75 and the output area 77. That is, the conductive portion 43c between the input are 75 and the output area 77 may not be present except for the current-limiting features.

The one or more burls 70 that are configured to apply the bias voltage may contact the input area 75 of the conductive portion 43c. The output area 77 of the conductive portion 43c may be electrically connected to the conductive edge 44. Thus, a bias potential may be applied to the patterning are 45 of the reflective portion 43a via: the supporting surface 42 of the support structure MT; the burls 70 of the support structure MT; the input area 75 of the conductive portion 43c of the patterning device MA; the one or more current-limiting features 76a-e of the conductive portion 43c of the patterning device; the output area 77 of the conductive portion 43c of the patterning device MA; the conductive edge 44; the perimeter area 47 of the reflective portion 43a; and the bridge 48.

In some embodiments, it may be preferable for the magnitude of the negative bias voltage applied to the perimeter area 47 of the patterning surface 40 to be greater than the magnitude of the negative bias voltage applied to the patterning area 45 of the patterning surface 40. Increasing the magnitude of the negative bias voltage applied to the perimeter area 47 of the patterning surface 40 may result in negatively charged contaminant particles being more effectively repelled from the patterning surface 40. However, increasing the magnitude of the negative bias voltage applied to the patterning area 45 of the patterning surface may result in an increase to the damage caused to the patterning area 45 of the patterning surface 40 through mechanisms such as implantation and blistering. Such damage is not important if it occurs to the perimeter area 47 of the patterning surface 40, because this area does not affect the image that is projected onto a substrate W. Thus, by making the magnitude of the negative bias voltage applied to the perimeter area 47 of the patterning surface 40 to be greater than the magnitude of the negative bias voltage applied to the patterning area 45 of the patterning surface 40, negatively charged contaminant particles can be more effectively repelled without increasing the damage to the patterning area 45 of the patterning surface 40. If the desired bias voltage for the patterning area 45 of the patterning surface 40 is between −1 V and −10 V, the desired bias voltage for the perimeter area 47 of the patterning surface may be, for example, between −10 V and −100 V.

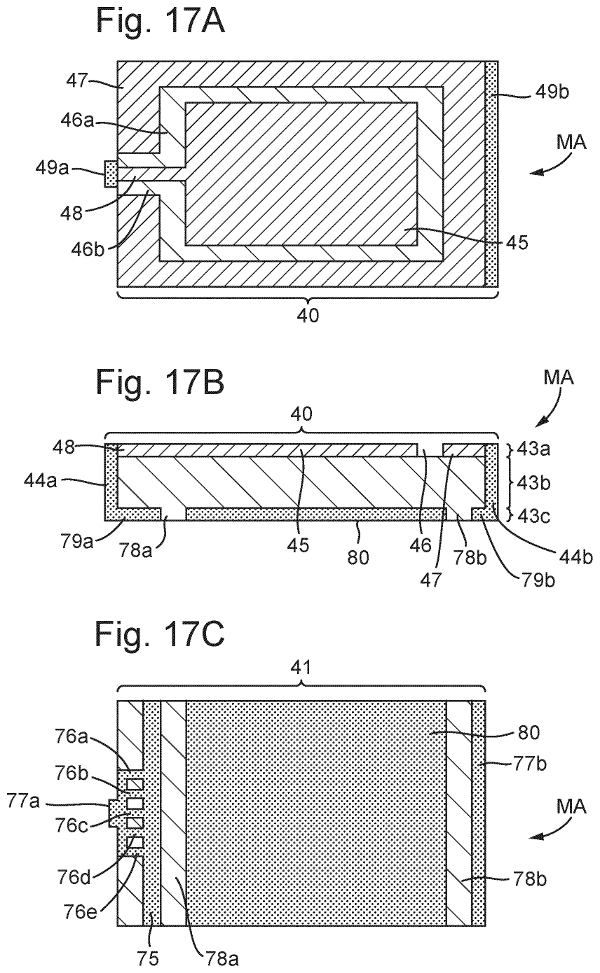

Differing bias voltages may be applied to the perimeter area 47 of the reflective portion 43a and the patterning area 45 of the reflective portion 43a by connecting the perimeter area 47 of the reflective portion 43a and the patterning area 45 of the reflective portion 43a to different voltage sources (not shown). For example, the perimeter area 47 of the reflective portion 43a may be connected to a first voltage source (not shown) and the patterning area 45 of the reflective portion 43a may be connected to a second voltage source (not shown). FIGS. 17A-17C depicts a patterning device MA which may be configured such that the perimeter area 47 of the reflective portion 43a and the patterning area 45 of the reflective portion 43a can be connected to the different voltage sources. FIG. 17A depicts a plan view of the patterning surface 40 of the patterning device; FIG. 17B depicts a cross-sectional view of the patterning device MA; and FIG. 17C depicts a plan view of the patterning device MA showing the non-patterning surface 41. The second voltage source may be switched off during loading and unloading processes. When the second voltage source is switched off, it may act as a ground.

The patterning surface 41 may comprise a patterning area 45, a border area 46a and a perimeter area 47, as explained above. An additional part 46b of the perimeter area 47 of the reflective portion 43a may be removed so that there is a discontinuity in the perimeter area 47 of the reflective portion 43a. A bridge may extend from the edge of the perimeter area 47 (i.e. the edge of the patterning device MA) to the patterning area 45 of the conductive portion 43a. At the edge of the perimeter area 47, the bridge 48 may be connected to a bridge contact 49a. The bridge contact 49a, the bridge 48 and the patterning area 45 of the reflective portion 43a may be electrically isolated from the perimeter area of the reflective portion 43a. The patterning device MA may further comprise a perimeter contact 49b. The perimeter contact 49b may be electrically connected to the perimeter area 47 of the reflective portion 43a. The bridge contact 49a and the perimeter contact 49b may be formed from the same material as the conductive portion 43c.

The patterning device MA may comprise two or more conductive edges 44a, 44b. The conductive edges 44a, 44b may each be as described above. The conductive edges 44a, 44b may comprise a patterning area conductive edge 44a and a perimeter area conductive edge 44b. The patterning area conductive edge 44a and the perimeter area conductive edge 44b may be electrically isolated from one another. The patterning area conductive edge 44a may be electrically connected to the bridge contact 49a. The perimeter area conductive edge 44b may be electrically connected to the perimeter contact 49b. The patterning area conductive edge 44a may only partially extend across an edge of the patterning device MA, such that the patterning area conductive edge 44a contacts the bridge contact 49a but not the perimeter area 47 of the reflective portion 43a

The conductive portion 43c may be patterned, as described above. The non-patterning surface 41 may comprise two or more insulative strips 78a, 78b. Between the two insulating strips 78a, 78b, there may be an unaffected area 80 of the conductive portion 43c. The unaffected area 80 of the conductive portion 43c may be responsible for the majority of the clamping. The unaffected area 80 may make up a majority of the non-patterning surface 41, as described above. On a first side of the non-patterning surface 41 (the side corresponding to the bridge patterning area conductive edge 44a and the bridge contact 49a), a first insulative strip 78a may separate the unaffected area 80 from a current-limiting component. The current-limiting component 74 may comprise an input area 75, an output area 77a and one or more current-limiting features 76a-76e. Each of the input area 75, the output area 77a and the one or more current-limiting features 76a-76e may be formed from the conductive portion 43c, as described above. The one or more current-limiting features 76a-76e may electrically connect the input area 75 and the output area 77a.

One or more burls 70 that are configured to apply bias voltage to the patterning area 45 may contact the input area 75 of the conductive portion 43c. The output area 77a of the conductive portion 43c may be electrically connected to the patterning area conductive edge 44a. Thus, a bias potential may be applied to the patterning area 45 of the reflective portion 43a via: the supporting surface 42 of the support structure MT; a subset of the burls 70 of the support structure MT; the input area 75 of the conductive portion 43c of the patterning device MA; the one or more current-limiting features 76a-e of the conductive portion 43c of the patterning device; the output area 77a of the conductive portion 43c of the patterning device MA; the patterning area conductive edge 44a; and the bridge 48.

A second insulative strip 78b may separate the unaffected area 80 of the conductive portion 43c from an input/output portion 77b. One or more burls 70 that are configured to apply bias voltage to the perimeter area 47 may contact the input/output area 77b of the conductive portion 43c. The input/output area 77b of the conductive portion 43c may be electrically connected to the perimeter area conductive edge 44b. Thus, a bias voltage may be applied to the perimeter area 47 of the reflective portion 43a via: the supporting surface 42 of the support structure MT; a subset of the burls 70 of the support structure MT; the input/output area 77b of the conductive portion 43c of the patterning device MA; and the perimeter area conductive edge 44b.

The bridge contact 49a and the perimeter area contact 49b may be a part of the patterning area conductive edge 44a and the perimeter area conductive edge 44b, respectively.

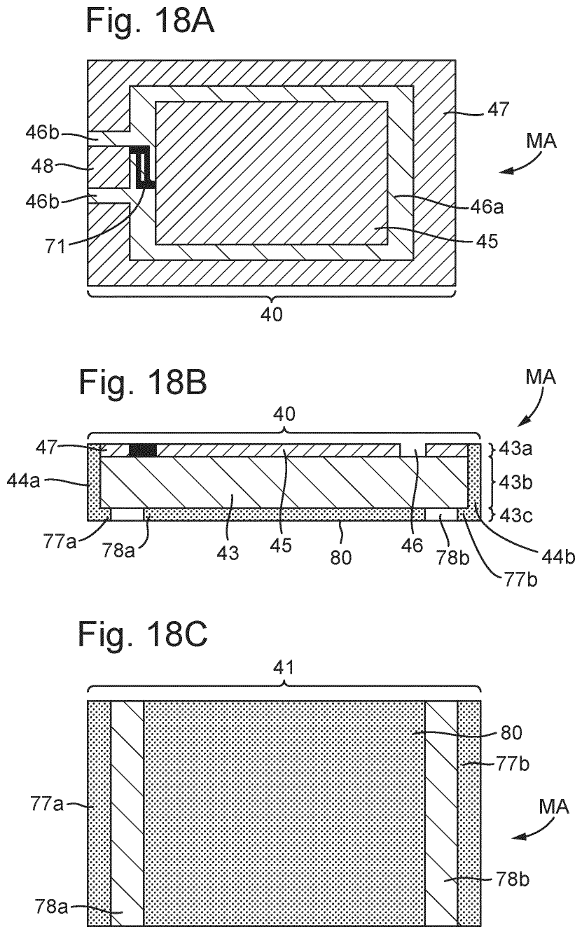

In the patterning device MA depicted in FIGS. 17A-17C, different bias voltages can be applied to the patterning area 45 and the perimeter area, and the current-limiting component is formed in the conductive portion 43c. In the patterning device MA depicted in FIGS. 18A-18B, different bias voltages can be applied to the patterning area 45 and the perimeter area, and the current-limiting component is formed in border area 46 the reflective portion 43a. Specifically, in the patterning device MA depicted in FIGS. 18A-18B, the current-limiting component is formed in the border area 46 of the reflective portion 43a. FIG. 18A depicts a plan view of the patterning surface 40 of the patterning device; FIG. 18B depicts a cross-sectional view of the patterning device MA; and FIG. 18C depicts a plan view of the patterning device MA showing the non-patterning surface 41.

The patterning surface 40 may comprise a patterning area 45, a border area 46 and a perimeter area 47. In addition to the reflective portion 43a removed from the border area 46, further parts 46b of the reflective portion 43a may be removed in the perimeter area 47. This may mean that there are two or more discontinuities 46b in the perimeter area 47 of the conductive portion 43a. Between the two discontinuities 46b, a bridge portion may be formed. The bridge portion 48 may be connected to a current-limiting component 71, which may be as described above. The bridge portion 48 may be electrically connected to the patterning area 45 of the reflective portion 43a via the current-limiting portion 71.

The patterning device MA may comprise two or more conductive edges 44a, 44b. The conductive edges 44a, 44b may each be as described above. The conductive edges 44a, 44b may comprise a patterning area conductive edge 44a and a perimeter area conductive edge 44b. The patterning area conductive edge 44a and the perimeter area conductive edge 44b may be electrically isolated from one another. The patterning area conductive edge 44a may be electrically connected to the bridge 48. The perimeter area conductive edge 44b may be electrically connected to the perimeter area 47 of the reflective portion 43a. The patterning area conductive edge 44a may only partially extend across an edge of the patterning device MA, such that the patterning area conductive edge 44a contacts the 48 but not the perimeter area 47 of the reflective portion 43a.

The non-patterning surface 41 may comprise two or more insulative strips 78a and 78b, which may be as described above. Between the insulative strips 78a, 78b, there may be an unaffected area 80, which may be as described above. On one side of the non-patterning surface 41 (the side corresponding to the patterning area conductive edge 44a and the bridge 48), the insulative strip 78a may separate the unaffected area 80 from a first input/output area 77a.

One or more burls 70 that are configured to apply bias voltage to the patterning area 45 may contact the first input/output area 77a the conductive portion 43c. The first input/output area 77a of the conductive portion 43c may be electrically connected to the patterning area conductive edge 44a. Thus, a bias potential may be applied to the patterning area 45 of the reflective portion 43a via: the supporting surface 42 of the support structure MT; a subset of the burls 70 of the support structure MT; the first input/output area 77a of the patterning device MA; the patterning area conductive edge 44a; the bridge 48; and the current-limiting component.

On an opposite side of the non-patterning surface 41, the insulative strip may separate the unaffected area 80 from a second input/output area 77b.

One or more burls 70 that are configured to apply bias voltage to the perimeter area may contact the second input/output area 77b of the conductive portion 43c. The second input/output area 77b of the conductive portion 43c may be electrically connected to the perimeter area conductive edge 44b. Thus, a bias potential may be applied to the patterning area 45 of the reflective portion 43a via: the support surface 42 of the support structure MT; a subset of the burls 70 of the support structure MT; the second input/output area 77b of the patterning device MA; and the perimeter area conductive edge 44b.

In the above embodiments, burls which contact the unaffected area 80 of a conductive portion 43c may be electrically isolated/floating or be grounded.

### Other Features

In the foregoing description, resistances and/or inductances have been described as being provided by components physically provided in the support structure MT, the patterning device MA or associated circuitry. However, this is not essential. Alternatively, the resistances and/or inductances described may be provided in a control system. For example, the resistances and/or inductances may be provided by a control system of the voltage source 67. This may mean that it is not necessary to integrate components such as resistors and/or inductors in the support structure MT, the patterning device MA or associated circuitry.

To further reduce the number of contaminant particles P attracted to the patterning surface 40 during EUV lithography, the pressure within the patterning device environment 90 could be further decreased. This means that less plasma is produced by the EUV radiation beam as it passes through the space inside the patterning device environment 90. Consequently, less of the contaminant particles P become negatively charged, so the problem of negatively charged particles P being attracted to the patterning surface 40 when the patterning surface 40 becomes positively charged during the pulse of EUV radiation is mitigated. Further, when the pressure is reduced, it is more likely that contaminant particles P generated within the patterning device environment 90 will be extracted. The pressure within the patterning device environment may be less than 10 Pa and preferably less than 4 Pa.

The patterning device voltage biasing system described above may be incorporated into a lithographic apparatus. The lithographic apparatus may be used for the manufacture of ICs.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

### Aspects of the Invention are Described in the Following Numbered Clauses

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.
1. A patterning device voltage biasing system for use in a lithographic apparatus, the patterning device voltage biasing system comprising:
a patterning device configured to impart a pattern to a beam of radiation, the patterning device comprising a patterning surface with a pattern thereon; and
a voltage source,
wherein the patterning device voltage biasing system is configured such that a voltage can be applied to the patterning surface of the patterning device by the voltage source.
2. The patterning device voltage biasing system of clause 1, further comprising a conductive member electrically connected to the voltage source, wherein:
the patterning device voltage system is capable of transitioning between a first arrangement and a second arrangement;
in the first arrangement, the conductive member is in contact with the patterning surface such that the voltage can be applied to the patterning surface; and
in the second arrangement, the conductive member is distanced from the patterning surface.
3. The patterning device voltage biasing system according to clause 2, wherein:
the conductive member is movable between a first position and a second position;
the conductive member is in the first position in the first arrangement of the patterning device voltage biasing system; and
the conductive member is in the second position in the second arrangement of the patterning device voltage biasing system.
4. The patterning device voltage biasing system according to clause 3, further comprising a conductive member actuator, wherein the conductive member actuator is configured to move the conductive member between the first position and the second position.
5. The patterning device voltage biasing system according to any of clauses 2 to 4, wherein the conductive member comprises a first end portion and a second end portion, the conductive member is supported at the first end portion, and the second end portion comprises a bevelled protrusion configured to contact the patterning surface.
6. The patterning device voltage biasing system according to clause 5, wherein the second end portion of the conductive member can rotate around the first end portion to move between the first position and the second position.
7. The patterning device voltage biasing system according to clause 6, wherein the angle of rotation of the second end portion around the first end portion between the first position and the second position is less than 10 degrees, preferably less than 5 degrees, and further preferably less than 1 degree.
8. The patterning device voltage biasing system according to any of clauses 2 to 7, wherein the conductive member is a leaf spring.
9. The patterning device voltage biasing system according to any of clauses 6 to 8, wherein the rotation of the second end portion around the first end portion comprises elastic deformation of the conductive member.
10. The patterning device voltage biasing system according to any of clauses 2 to 9, wherein the conductive member is configured to contact a region of the patterning surface where no pattern is present.
11. The patterning device voltage biasing system according to any of clauses 2 to 10, further comprising a patterning device holder configured to clamp the patterning device by exerting an attractive force on a non-patterning surface of the patterning device, which is a surface opposite the patterning surface.
12. The patterning device voltage biasing system according to any of clauses 2 to 10, wherein: a first direction is a direction perpendicular to the patterning surface and away from patterning device holder;
the patterning device voltage biasing system further comprises a landing portion, wherein the landing portion is disposed such that, when the patterning device is clamped by the patterning device holder, the patterning surface is separated from the landing portion by a displacement in the first direction.
13. The patterning device voltage biasing system of clause 12, wherein the conductive member is movable to a third position in which the conductive member is in contact with the landing portion.
14. The patterning device voltage biasing system according to any of clauses 1 to 13, wherein the conductive member is connected to the voltage source via a resistor or an inductor.
15. The patterning device according to any of clauses 1 to 13, wherein a reflective portion of the patterning device comprises a patterning area and a perimeter area, the conductive member is configured to contact the perimeter area of the reflective portion, the patterning area of the reflective portion is electrically isolated from the perimeter area of the reflective portion, and a resistor or an inductor is disposed between the perimeter area of the reflective portion and the patterning area of the reflective portion.
16. The patterning device voltage biasing system according to any of clauses 2 to 15, wherein the conductive member is connected to the voltage source via a diode.
17. The patterning device voltage biasing system according to any of clauses 2 to 16, wherein the conductive member is connected to the voltage source via a switch.
18. The patterning device voltage biasing system according to clause 17, wherein the switch can be opened and closed at a frequency that is greater than 49 kHz, preferably greater than 59 kHz, and further preferably greater than 99 kHz.
19. The patterning device voltage biasing system according to clause 17 or clause 18, wherein the frequency at which the switch opens and closes is synchronised with a frequency of generation of a beam of radiation in the lithographic apparatus.
20. The patterning device voltage biasing system according to any of clauses 2 to 19, wherein there are a plurality of conductive members distributed circumferentially around the patterning device.
21. The patterning device voltage biasing system according to any of clauses 12 to 20, wherein there are a plurality of landing members distributed circumferentially around the patterning device.
22. The patterning device voltage biasing system of clause 1, wherein:
the patterning device further comprises a non-patterning surface opposite the patterning surface;
the patterning device voltage biasing system further comprises a patterning device holder, which comprises a plurality of burls, wherein distal ends of one or more of the plurality of burls are in contact with the non-patterning surface of the patterning device;
at least a portion of the non-patterning surface can be electrically connected to the voltage source via one or more of the plurality of burls; and
the patterning surface and non-patterning surface are electrically connected.
23. The patterning device voltage biasing system of clause 1, wherein:
the patterning device further comprises a non-patterning surface on an opposite side of the patterning device to the patterning surface, wherein the patterning surface and non-patterning surface are substantially electrically isolated from one another;
the patterning device voltage biasing system further comprises a patterning device holder, which comprises a plurality of burls, wherein distal ends of one or more of the plurality of burls are arranged to contact with the non-patterning surface of the patterning device;
one or more of the burls are configured to electrically connect the non-patterning surface to the voltage source.
24. The patterning device voltage biasing system according to clause 22, wherein the patterning surface and the voltage source are connected via a first current-limiting component.
25. The patterning device voltage biasing system according to clause 22 or 24, wherein the patterning surface and the voltage source are connected via a timing switch.
26. The patterning device voltage biasing system according to clause 25, wherein the patterning device voltage biasing system is configured such that the switch can be opened and closed at a frequency that is greater than 49 kHz, preferably greater than 59 kHz, and further preferably greater than 99 kHz.
27. The patterning device voltage biasing system according to clause 25 or 26, wherein the frequency at which the timing switch opens and closes is synchronised with a frequency of generation of a beam of radiation in the lithographic apparatus, such that the patterning surface is electrically connected to the voltage source between pulses of radiation.
28. The patterning device voltage biasing system according to clause 24, wherein the first current-limiting component is disposed between the plurality of burls and the voltage source.
29. The patterning device voltage biasing system according to clause 24, wherein the first current-limiting component is formed in the non-patterning surface of the patterning device the patterning surface of the patterning device, outside a patterning area.
30. The patterning device voltage biasing system according to clause 29, wherein a reflective portion of the patterning device comprises a patterning area and a perimeter area, and the patterning area of the reflective portion is electrically isolated from the perimeter area of the reflective portion, and the first current-limiting component is disposed between the perimeter area of the reflective portion and the patterning area of the reflective portion.
31. The patterning device of any of the preceding clauses, wherein the non-patterning surface can be electrically connected to the ground via the one or more of the plurality of burls.
32. The patterning device voltage biasing system according to any of clause 31, wherein the patterning device voltage biasing system further comprises a mode-changing switch configured such that the non-patterning surface is either connected to (i) the power supply via the one or more of the plurality of burls or (ii) the ground via the one or more of the plurality of burls.
33. The patterning device voltage biasing system according to clauses 31 or 32, wherein the non-patterning surface can be electrically connected to the ground via a second current-limiting component.
34. The patterning device voltage system according to clause 33, wherein the second current-limiting component is configured such when the patterning device is discharged to the ground, the current in the patterning device does not exceed 1000 mA, preferably does not exceed 500 mA and further preferably does not exceed 100 mA.
35. The patterning device voltage biasing system according to clauses 33 or 34, wherein the second current-limiting component comprises a resistor with a resistance that is greater than 1Ω, preferably greater than 10Ω and further preferably greater than 200Ω, and less than 10 kΩ, preferably less than 1 kΩ, and further preferably less than 400Ω.
36. The patterning device voltage biasing system according to clause 33, wherein the second current-limiting component comprises an inductor.
37. The patterning device voltage biasing system according to any of clauses 33 to 36, wherein the second current-limiting component is disposed between the plurality of burls and the ground.
38. The patterning device voltage biasing system according to any of clauses 29 to 32, wherein the second current-limiting component is formed in a reflective portion of the patterning device or a conductive portion of the patterning device.
39. The patterning device voltage biasing system according to 38, wherein a reflective portion of the patterning device comprises a patterning area and a perimeter area, and the patterning area of the reflective portion is electrically isolated from the perimeter area of the reflective portion, and the second current-limiting component is disposed between the perimeter area of the reflective portion and the patterning area of the reflective portion.
40. The patterning device voltage biasing system according to any of clauses 31 to 39, wherein the patterning device voltage biasing system is configured such that the non-patterning surface is connected to the ground via the one or more of the plurality of burls whilst the patterning device is loaded onto the patterning device holder and/or unloaded from the patterning device holder.
41. The patterning device voltage biasing system of any of the preceding clauses, wherein the bias voltage is negative.
42. The patterning device voltage biasing system of any of the preceding clauses, further comprising a controller configured to control the bias voltage to be positive during times when the lithographic apparatus generates pulses of EUV radiation and negative between times when the lithographic apparatus generates the pulses of EUV radiation.
43. The patterning device voltage biasing system of any of the preceding clauses, wherein the voltage source is configured to supply the negative bias voltage to the patterning surface with a magnitude that is greater than 0.5V, preferably greater than 1 V, less than 10 V, preferably less than 5 V and further preferably less than 3 V, and/or the voltage source is configured to supply the positive bias voltage to the patterning surface with a magnitude that is greater 1 V and preferably greater than 5 V, less than 100 V and preferably less than 50 V.
44. The patterning device voltage biasing system of any of the preceding clauses, further comprising a patterning device environment in which the patterning device is located, wherein the pressure within the patterning device environment is less than 10 Pa, and preferably less than 4 Pa.
45. A lithographic apparatus comprising the patterning device voltage biasing system according to any of the preceding clauses.
46. A method of reducing contamination on a patterning surface of a patterning device in a lithographic apparatus, the method comprising:
a contacting step in which a conductive member is brought into contact with the patterning surface;
a voltage biasing step in which a voltage is provided to the patterning surface from a voltage source, via the conductive member.
47. The method according to clause 46, wherein the contacting step comprises moving the conductive member from a first position to a second position.
48. The method according to clause 46 or 47, wherein:
the conductive member comprises a first end portion and a second end portion;
the conductive member is supported at the first end portion;
the second end portion comprises a bevelled protrusion configured to contact the patterning surface; and
the contacting step comprises the rotation of the second end portion about the first end portion.
49. The method according to clause 48, wherein the rotation of the second end portion around the first end portion in the contacting step is less than 10 degrees, preferably less than 5 degrees, and further preferably less than 1 degree.
50. The method according to clauses 48 or 49, wherein the conductive member is a leaf spring, and the rotation of the first end portion around the second end portion comprises elastic deformation of the leaf spring.
51. The method according to any of clauses 46 to 50, further comprising a clamping step, wherein the patterning device is clamped to a patterning device support.
52. The method according to clause 51, further comprising a landing step, wherein:
the patterning device is unclamped from the patterning device support; and
the conductive member is moved from the first position or the second position to a third position, wherein, in the third position, the conductive member is in contact with the landing portion.
53. The method according to clause 52, wherein the movement of the conductive member to the third position comprises rotation of the second end portion around the first end portion in a direction that is opposite to that of the rotation from the first position to the second position.
54. The method according to any of clauses 46 to 53, wherein the conductive member is connected to the voltage source via a timing switch, and the voltage biasing step comprises the opening and closing of the timing switch at a frequency which is in accordance with a frequency of generation of a beam of radiation in the lithographic apparatus, such that the voltage is provided to the patterning surface between pulses of radiation.
55. The method according to any of clauses 46 to 54, further comprising, when the patterning device is loaded onto the patterning device holder and/or when the patterning device is unloaded from the patterning device holder, discharging the patterning device by connecting the patterning device to the ground via one or more of a plurality of burls.
56. A method of reducing contamination on a patterning surface of a patterning device in a lithographic apparatus, the method comprising:
clamping the patterning device with a patterning device support, wherein a non-patterning surface of the patterning device is in contact with one or more of a plurality of burls disposed on a surface of the patterning device support, and the non-patterning surface is opposite the patterning surface; and
providing a voltage to the patterning surface of the patterning device from a voltage source via the one or more of the plurality of burls and the non-patterning surface.
57. The method according to clause 56, wherein the patterning surface and the non-patterning surface are electrically connected.
58. The method according to clause 56, wherein the patterning surface is electrically isolated from the non-patterning surface, and the providing the voltage to the patterning surface comprises capacitively providing the voltage to the patterning surface.
59. The method according to clause 56 or 57, wherein the patterning surface is electrically connected to the voltage source via a timing switch, and the provision of the voltage to the patterning surface comprises the opening and closing of the switch at a frequency which is controlled in accordance with a frequency of generation of a beam of radiation in the lithographic apparatus, such that the voltage is provided to the patterning surface between pulses of radiation.
60. The method according to clauses 56 to 59, further comprising, when the patterning device is loaded onto the patterning device holder and/or when the patterning device is unloaded from the patterning device holder, discharging the patterning device by connecting the patterning device to the ground via the one or more of the plurality of burls.
61. The method according to clause 60, wherein the discharging of the patterning device and the providing the voltage to the patterning surface is controlled such that the current in the patterning surface does not exceed 1000 mA, preferably does not exceed 500 mA and further preferably does not exceed 100 mA.
62. The method according to any of clauses 46 to 61, further comprising restricting the current in the patterning surface using a first current-limiting component disposed between the voltage source and the patterning surface.
63. The method according to any of clauses 46 to 62, further comprising restricting the current in the patterning surface using a second current-limiting component disposed between the ground and the patterning surface.
64. The method according to any of clauses 46 to 63, wherein the patterning device is positioned in a patterning device environment, and the method further comprises a step of reducing the pressure within the patterning device environment to be less than 10 Pa, and preferably less than 4 Pa.
65. The method according to any of clauses 46 to 64, wherein the bias voltage is negative.
66. The method according to any clauses 46 to 65, wherein the bias voltage is positive during times when the lithographic apparatus generates pulses of EUV radiation and the bias voltage is negative between times when the lithographic apparatus generates the pulses of EUV radiation.
67. The method according to any of clauses 46 to 66, wherein the magnitude of the voltage provided to the patterning surface is greater than 0.5 V, preferably greater than 1 V, less than 10 V, preferably less than 5 V, and further preferably less than 3 V.
68. A method of manufacturing a device comprising the method of reducing contamination on a patterning surface of a patterning device according to any of clauses 46 to 67.

1-68. (canceled)

69. A patterning device voltage biasing system for use in a lithographic apparatus, the patterning device voltage biasing system comprising:
a patterning device configured to impart a pattern to a beam of radiation, the patterning device comprising a patterning surface with a pattern thereon; and
a voltage source,
wherein the patterning device voltage biasing system is configured such that a voltage is applied to the patterning surface of the patterning device by the voltage source.

70. The patterning device voltage biasing system of claim 69, further comprising a conductive member electrically connected to the voltage source, wherein:
the patterning device voltage system is capable of transitioning between a first arrangement and a second arrangement;
in the first arrangement, the conductive member is in contact with the patterning surface such that the voltage is applied to the patterning surface; and
in the second arrangement, the conductive member is distanced from the patterning surface.

71. The patterning device voltage biasing system of claim 69, wherein:
the patterning device further comprises a non-patterning surface opposite the patterning surface;
the patterning device voltage biasing system further comprises a patterning device holder, which comprises a plurality of burls;
distal ends of one or more of the plurality of burls are in contact with the non-patterning surface of the patterning device;
at least a portion of the non-patterning surface is electrically connected to the voltage source via one or more of the plurality of burls; and
the patterning surface and non-patterning surface are electrically connected.

72. The patterning device voltage biasing system of claim 69, wherein:
the patterning device further comprises a non-patterning surface on an opposite side of the patterning device to the patterning surface;
the patterning surface and non-patterning surface are substantially electrically isolated from one another;
the patterning device voltage biasing system further comprises a patterning device holder, which comprises a plurality of burls;
distal ends of one or more of the plurality of burls are arranged to contact with the non-patterning surface of the patterning device; and
one or more of the plurality of burls are configured to electrically connect the non-patterning surface to the voltage source.

73. The patterning device voltage biasing system of claim 71, wherein the patterning surface and the voltage source are connected via a first current-limiting component.

74. The patterning device voltage biasing system according to claim 71, wherein the first current-limiting component is disposed between the plurality of burls and the voltage source.

75. The patterning device voltage biasing system according to claim 71, wherein the first current-limiting component is formed in the non-patterning surface of the patterning device the patterning surface of the patterning device, outside a patterning area.

76. The patterning device voltage biasing system of claim 69, wherein the non-patterning surface is electrically connected to the ground via the one or more of the plurality of burls.

77. The patterning device voltage biasing system of claim 69, wherein the patterning device voltage biasing system further comprises a mode-changing switch configured such that the non-patterning surface is either connected to (i) the power supply via the one or more of the plurality of burls or (ii) the ground via the one or more of the plurality of burls.

78. The patterning device voltage biasing system according to claim 76, wherein the patterning device voltage biasing system is configured such that the non-patterning surface is connected to the ground via the one or more of the plurality of burls while the patterning device is loaded onto the patterning device holder and/or unloaded from the patterning device holder.

79. The patterning device voltage biasing system of claim 69, wherein the bias voltage is negative.

80. The patterning device voltage biasing system of claim 69, wherein:
the voltage source is configured to supply the negative bias voltage to the patterning surface with a magnitude that is greater than 0.5V, greater than 1 V, less than 10 V, less than 5 V or less than 3 V, and/or
the voltage source is configured to supply the positive bias voltage to the patterning surface with a magnitude that is greater 1 V, greater than 5 V, less than 100 V or less than 50 V.

81. A lithographic apparatus comprising:
the patterning device voltage biasing system of claim 69.

82. A method of reducing contamination on a patterning surface of a patterning device in a lithographic apparatus, the method comprising:
contacting such that a conductive member is brought into contact with the patterning surface;
a voltage biasing in which a voltage is provided to the patterning surface from a voltage source, via the conductive member.

83. A method of reducing contamination on a patterning surface of a patterning device in a lithographic apparatus, the method comprising:
clamping the patterning device with a patterning device support, wherein a non-patterning surface of the patterning device is in contact with one or more of a plurality of burls disposed on a surface of the patterning device support, and the non-patterning surface is opposite the patterning surface; and
providing a voltage to the patterning surface of the patterning device from a voltage source via the one or more of the plurality of burls and the non-patterning surface.

84. The method of claim 83, wherein the patterning surface and the non-patterning surface are electrically connected.

85. The method of claim 83, further comprising, in response to the patterning device being loaded onto the patterning device holder and/or in response to the patterning device being unloaded from the patterning device holder, discharging the patterning device by connecting the patterning device to the ground via the one or more of the plurality of burls.

86. The method of claim 82, further comprising restricting the current in the patterning surface using a first current-limiting component disposed between the voltage source and the patterning surface.

87. The method of claim 82, wherein the bias voltage is negative.

88. The method according to any of claim 82, wherein a magnitude of the voltage provided to the patterning surface is greater than 0.5 V, greater than 1 V, less than 10 V, less than 5 V, or less than 3 V.
